(19) United States
(12) Patent Application Publication
(10) Pub. No.: US 2024/0233601 A9
(43) Pub. Date: Jul. 11, 2024

(54) PIXEL CIRCUIT, DRIVING METHOD THEREOF, DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Gang WANG, Beijing (CN); Kai ZHANG, Beijing (CN); Xinyu WEI, Beijing (CN); Qiang FU, Beijing (CN); Xingrui CAI, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/548,184

(22) PCT Filed: Jul. 13, 2022
(86) PCT No.: PCT/CN2022/105458

§ 371 Date: Aug. 28, 2023

(30) Foreign Application Priority Data
Jul. 30, 2021 (WO) PCT/CN2021/109894
Aug. 5, 2021 (CN) 202110897722.1

(51) Int. Cl. G09G 3/3225

(52) U.S. Cl. CPC G09G 3/3225; G09G 2300/0408; G09G 2300/0426; G09G 2300/0819; G09G 2300/0842; G09G 2310/08; G09G 2320/0233; G09G 2320/0247

(57) ABSTRACT

In the pixel circuit, the data writing-in circuit is configured to control to connect the data line and the second terminal of the driving circuit under the control of a first scanning signal provided by the first scanning line; the compensation control circuit is configured to control to connect the first terminal of the driving circuit and the connection node under the control of a second scanning signal provided by the second scanning line; the first control circuit is configured to control to connect the control terminal of the driving circuit and the connection node under the control of the first scanning signal.

### CROSS-REFERENCE TO RELATED APPLICATIONS

This application claims priorities of PCT Application No. PCT/CN2021/109894 filed on Jul. 30, 2021 and the Chinese patent application No. 202110897722.1 filed on Aug. 5, 2021, which are incorporated herein by reference in their entireties.

### TECHNICAL FIELD

The present disclosure relates to the field of display technology, in particular to a pixel circuit, a driving method thereof, a display substrate and a display device.

### BACKGROUND

With the popularity of active-matrix organic light emitting diode (AMOLED) displays in the mid-to-high-terminal market, the quality requirements of AMOLED displays are getting higher and higher, and more refine requirements are placed on the design.

At present, in the process of writing-in data and compensating the driving transistor in the AMOLED display screen, the problem of insufficient data writing-in is prone to occur. Moreover, the display screen also needs a high voltage to display a black picture, and there is a difference in display brightness between odd rows and even rows.

### SUMMARY

An object of the present disclosure is to provide a pixel circuit, a driving method thereof, a display substrate and a display device.

In order to achieve the above-mentioned object, the present disclosure provides the following technical solutions.

In one aspect, the present disclosure provides in some embodiments a pixel circuit, including: a driving circuit, a data writing-in circuit, a compensation control circuit and a first control circuit; wherein the data writing-in circuit is respectively coupled to a first scanning line, a data line, and a second terminal of the driving circuit, and is configured to control to connect the data line and the second terminal of the driving circuit under the control of a first scanning signal provided by the first scanning line; the compensation control circuit is respectively coupled to a second scanning line, a first terminal of the driving circuit and a connection node, and is configured to control to connect the first terminal of the driving circuit and the connection node under the control of a second scanning signal provided by the second scanning line; the first control circuit is respectively coupled to the first scanning line, a control terminal of the driving circuit and the connection node, and is configured to control to connect the control terminal of the driving circuit and the connection node under the control of the first scanning signal.

Optionally, the pixel circuit further includes: a first initialization circuit, the first initialization circuit is respectively coupled to an initialization control line, a first initialization voltage line and the control terminal of the driving circuit, and is configured to control to connect the first initialization voltage line and the control terminal of the driving circuit under the control of an initialization control signal provided by the initialization control line.

Optionally, the pixel circuit further includes: a first initialization circuit, wherein the first initialization circuit is respectively coupled to an initialization control line, a first initialization voltage line and the connection node, and is configured to control to connect the first initialization voltage line and the connection node under the control of an initialization control signal provided by the initialization control line.

Optionally, the pixel circuit further includes: a reset circuit, wherein the reset circuit is respectively coupled to a third scanning line, a reset voltage line and the second terminal of the driving circuit, is configured to control to connect the reset voltage line and the second terminal of the driving circuit under the control of a third scanning signal provided by the third scanning line.

Optionally, the pixel circuit further includes: a reset circuit, the reset circuit is respectively coupled to a third scanning line, a reset voltage line and the first terminal of the driving circuit, and is configured to control to connect the reset voltage line and the first terminal of the driving circuit under the control of a third scanning signal provided by the third scanning line.

Optionally, the pixel circuit further comprises: a light emitting control circuit, an energy storage circuit and a light emitting element; the light emitting control circuit is respectively coupled to a light emitting control line, the first terminal of the driving circuit and the light emitting element, and is configured to control to connect the first terminal of the driving circuit and the light emitting element under the control of a light emitting control signal provided by the light emitting control line; the light emitting control circuit is also coupled to a first voltage line and the second terminal of the driving circuit, and is configured to control to connect the first voltage line and the second terminal of the driving circuit under the control of the light emitting control signal; the energy storage circuit is respectively coupled to the control terminal of the driving circuit and the first voltage line.

Optionally, the pixel circuit further includes: a second initialization circuit and a light emitting element; the second initialization circuit is respectively coupled to the third scanning line, a second initialization voltage line and the light emitting element, and is configured to control to connect the second initialization voltage line and the light emitting element under the control of the third scanning signal provided by the third scanning line.

Optionally, the pixel circuit further comprises a first initialization circuit, the first initialization circuit is coupled to a first initialization voltage line, and the first initialization voltage line is multiplexed as the reset voltage line.

Optionally, the compensation control circuit includes a first transistor, the driving circuit includes a third transistor, the data writing-in circuit includes a fourth transistor, and the first control circuit includes a ninth transistor; a gate electrode of the first transistor is coupled to the second scanning line, a first electrode of the first transistor is coupled to a second electrode of the third transistor, and a second electrode of the first transistor is coupled to the connection node; a gate electrode of the fourth transistor is coupled to the first scanning line, a first electrode of the fourth transistor is coupled to the data line, and a second electrode of the fourth transistor is coupled to a first electrode of the third transistor; a gate electrode of the ninth transistor is coupled to the first scanning line, a first electrode of the ninth transistor is coupled to the connection node, and a second electrode of the ninth transistor is coupled to a gate electrode of the third transistor.

Optionally, the first initialization circuit comprises a second transistor, a gate electrode of the second transistor is coupled to the initialization control line, a first electrode of the second transistor is coupled to the first initialization voltage line, and a second electrode of the second transistor is coupled to the control terminal of the driving circuit.

Optionally, the first initialization circuit comprises a second transistor, a gate electrode of the second transistor is coupled to the initialization control line, and a first electrode of the second transistor is connected to the first initialization voltage line, and a second electrode of the second transistor is coupled to the connection node.

Optionally, the reset circuit comprises an eighth transistor; a gate electrode of the eighth transistor is coupled to the third scanning line, a first electrode of the eighth transistor is coupled to the reset voltage line, and a second electrode of the eighth transistor is coupled to the second terminal of the driving circuit.

Optionally, the reset circuit comprises an eighth transistor; a gate electrode of the eighth transistor is coupled to the third scanning line, a first electrode of the eighth transistor is coupled to the reset voltage line, and a second electrode of the eighth transistor is coupled to the first terminal of the driving circuit.

Optionally, the light emitting control circuit comprises a fifth transistor and a sixth transistor; a gate electrode of the fifth transistor is coupled to the light emitting control line, a first electrode of the fifth transistor is coupled to the first voltage line, and a second electrode of the fifth transistor is coupled to the second terminal of the driving circuit; a gate electrode of the sixth transistor is coupled to the light emitting control line, a first electrode of the sixth transistor is coupled to one terminal of the driving circuit, and a second electrode of the sixth transistor is coupled to the light emitting element.

Optionally, the second initialization circuit comprises a seventh transistor, a gate electrode of the seventh transistor is coupled to the third scanning line, a first electrode of the seventh transistor is coupled to the second initialization voltage line, and a second electrode of the seventh transistor is coupled to the light emitting element.

In a second aspect, an embodiment of the present disclosure provides a driving method, applied to the pixel circuit, wherein the display period includes a writing-in compensation phase, and the writing-in compensation phase includes: a writing-in control phase and a non-writing-in control phase; the driving method includes: in the entire writing-in compensation phase, the compensation control circuit controlling to connect the first terminal of the driving circuit and the connection node under the control of the second scanning signal; in the writing-in control phase, the data writing-in circuit controlling to connect the data line and the second terminal of the driving circuit under the control of the first scanning signal; controlling to connect the control terminal of the driving circuit and the connection node under the control of the first scanning signal; in the non-writing-in control phase, the data writing-in circuit controlling to not connect the data line and the second terminal of the driving circuit under the control of the first scanning signal; the first control circuit controlling to not connect the control terminal of the driving circuit and the connection node under the control of the first scanning signal.

Optionally, an end time of the writing-in compensation phase is the same as an end time of the writing-in control phase.

Optionally, the display period further includes an initialization phase; the driving method further includes: in the initialization phase, the first initialization circuit in the pixel circuit controlling to connect the first initialization voltage line and the control terminal of the driving circuit under the control of the initialization control signal; or in the initialization phase, the first initialization circuit controlling to connect the first initialization voltage line and the connection node under the control of the initialization control signal, and the first control circuit controlling to connect the control terminal of the driving circuit and the connection node under the control of the first scanning signal.

Optionally, the display period further includes a bias compensation phase and a light emitting phase, the driving method includes: in the bias compensation phase, the reset circuit controlling to connect the reset voltage line and the second terminal of the driving circuit under the control of the third scanning signal; or controlling to connect between the reset voltage line and the first terminal of the driving circuit; in the light emitting phase, the light emitting control circuit in the pixel circuit controlling to connect the first voltage line and the second terminal of the driving circuit under the control of the light emitting control signal, and controlling to connect the first terminal of the driving circuit and the light emitting element, and the driving circuit driving the light emitting element to emit light.

In a third aspect, an embodiment of the present disclosure provides a display substrate, comprising a base substrate and a plurality of sub-pixels arranged on the base substrate, wherein the sub-pixel comprises the pixel circuit; the sub-pixel further includes: a data line, a first scanning line and a second scanning line; wherein the data line includes at least a portion extending along a first direction, the first scanning line includes at least a portion extending along a second direction, the third scanning line includes at least a portion extending along the second direction, the second direction intersects the first direction; a data writing-in circuit, respectively coupled to the first scanning line, the data line and the second terminal of the driving circuit, configured to control to connect the data line and the second terminal of the driving circuit under the control of the first scanning signal provided by the first scanning line; a compensation control circuit, respectively coupled to the second scanning line, the first terminal of the driving circuit and the connection node, configured to control to connect the first terminal of the driving circuit and the connection node under the control of the second scanning signal provided by the second scanning line; a first control circuit, respectively coupled to the first scanning line, the control terminal of the driving circuit and the connection node, configured to control to connect the control terminal of the driving circuit and the connection node under the control of the first scanning signal.

Optionally, the first control circuit includes a ninth transistor, the ninth transistor includes a ninth active layer, and the ninth active layer includes at least a portion extending along the first direction; the driving circuit includes a third transistor, an orthographic projection of a gate electrode of the third transistor on the base substrate and an orthographic projection of the ninth active layer on the base substrate are arranged along the first direction; the sub-pixel further includes: a first connection pattern, a second electrode of the ninth transistor is coupled to the gate electrode of the third transistor through the first connection pattern.

Optionally, the first initialization circuit in the pixel circuit includes a second transistor, the second transistor includes a second active layer, and the second active layer includes at least a portion extending along the first direction; an orthographic projection of a part of the second active layer on the base substrate and an orthographic projection of a part of the ninth active layer on the base substrate are arranged along the second direction; the sub-pixel also includes a second connection pattern, and the second connection pattern includes a portion extending along the first direction and a portion extending along the second direction; a second electrode of the second transistor is coupled to the first connection pattern through the second connection pattern.

Optionally, the first initialization circuit in the pixel circuit includes a second transistor, the second transistor includes a second active layer, and the second active layer includes at least a portion extending along the first direction; an orthographic projection of a part of the second active layer on the base substrate and an orthographic projection of a part of the ninth active layer on the base substrate are arranged along the second direction; the sub-pixel also includes a third connection pattern, and the third connection pattern includes at least a portion extending along the second direction; a second electrode of the second transistor is coupled to the first electrode of the ninth transistor through the third connection pattern.

Optionally, an orthographic projection of the third connection pattern on the base substrate at least partially overlaps an orthographic projection of the first scanning line on the base substrate.

Optionally, the sub-pixel further comprises an initialization control line, and the orthographic projection of the third connection pattern on the base substrate at least partially overlaps an orthographic projection of the initialization control line on the base substrate.

In a fourth aspect, an embodiment of the present disclosure provides a display device including the display substrate.

### BRIEF DESCRIPTION OF THE DRAWINGS

The drawings described here are used to provide a further understanding of the present disclosure, and constitute a part of the present disclosure. The schematic embodiments of the present disclosure and their descriptions are used to explain the present disclosure, and do not constitute improper limitations to the present disclosure.

FIG. 1 is a first structural diagram of a pixel circuit provided by an embodiment of the present disclosure;

FIG. 2 is a second structural diagram of a pixel circuit provided by an embodiment of the present disclosure;

FIG. 3 is a first circuit diagram of a pixel circuit provided by an embodiment of the present disclosure;

FIG. 4 is a first timing diagram provided by an embodiment of the present disclosure;

FIG. 5 is a third structural diagram of a pixel circuit provided by an embodiment of the present disclosure;

FIG. 6 is a second circuit diagram of a pixel circuit provided by an embodiment of the present disclosure;

FIG. 7 is a second timing diagram provided by an embodiment of the present disclosure;

FIG. 8 is a third circuit diagram of a pixel circuit provided by an embodiment of the present disclosure;

FIG. 9 is a schematic diagram of the voltage of the N1 node provided by an embodiment of the present disclosure;

FIG. 10 is a current difference diagram of sub-pixels in odd rows and even rows provided by an embodiment of the present disclosure;

FIG. 11 is a schematic layout diagram of a display substrate provided by an embodiment of the present disclosure;

FIG. 12 is a schematic diagram of the stacking of the second gate metal layer to the third gate metal layer provided by an embodiment of the present disclosure;

FIG. 13 is a schematic cross-sectional view of an eighth transistor provided by an embodiment of the present disclosure.

FIG. 14 is a schematic layout diagram corresponding to FIG. 3;

FIG. 15 is a schematic layout diagram of the poly active layer in FIG. 14;

FIG. 16 is a schematic layout diagram of the first gate metal layer in FIG. 14;

FIG. 17 is a schematic layout diagram of the second gate metal layer in FIG. 14;

FIG. 18 is a schematic layout diagram of the oxide active layer in FIG. 14;

FIG. 19 is a schematic layout diagram of the third gate metal layer in FIG. 14;

FIG. 20 is a schematic diagram of the first connecting hole in FIG. 14;

FIG. 21 is a schematic diagram of the second connecting hole in FIG. 14;

FIG. 22 is a schematic layout diagram of the first source-drain metal layer in FIG. 14;

FIG. 23 is a schematic diagram of a via hole formed by the passivation layer in FIG. 14;

FIG. 24 is a schematic diagram of a via hole formed by the first planarization layer in FIG. 14;

FIG. 25 is a schematic layout diagram of the second source-drain metal layer in FIG. 14;

FIG. 26 is a schematic diagram of the first layout corresponding to FIG. 6;

FIG. 27 is a schematic layout diagram of the second gate metal layer in FIG. 26;

FIG. 28 is a schematic layout diagram of the oxide active layer in FIG. 26;

FIG. 29 is a schematic layout diagram of the third gate metal layer in FIG. 26;

FIG. 30 is a schematic diagram of the second connecting hole in FIG. 26;

FIG. 31 is a schematic layout diagram of the first source-drain metal layer in FIG. 26;

FIG. 32 is a schematic diagram of a second layout corresponding to FIG. 6;

FIG. 33 is a schematic layout diagram of the first source-drain metal layer in FIG. 32;

FIG. 34 is a schematic diagram of a third layout corresponding to FIG. 6;

FIG. 35 is a schematic layout diagram of the first source-drain metal layer in FIG. 34;

FIG. 36 is a fourth circuit diagram of a pixel circuit provided by an embodiment of the present disclosure;

FIG. 37 is a third timing diagram provided by an embodiment of the present disclosure.

### DETAILED DESCRIPTION

In order to further illustrate the pixel circuit, the driving method thereof, the display substrate, and the display device provided by the embodiments of the present disclosure, a detailed description will be given below in conjunction with the accompanying drawings.

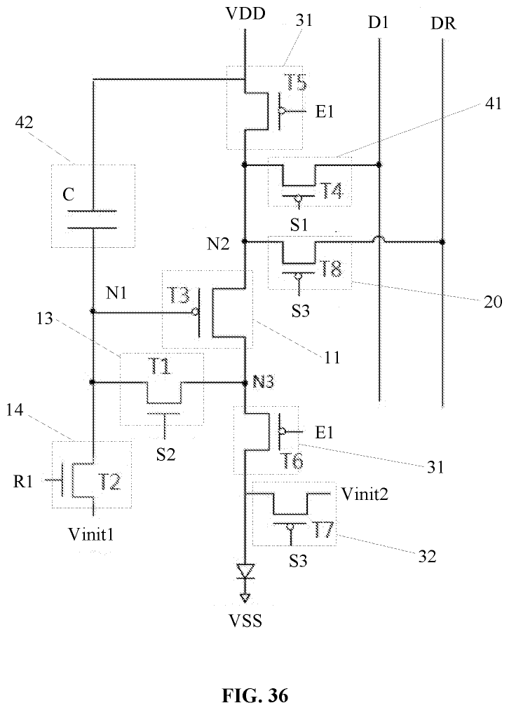

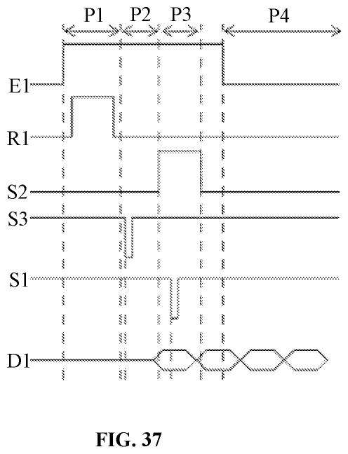

As shown in FIG. 36 and FIG. 37, the present disclosure provides a pixel circuit, the pixel circuit includes a first transistor T1, a second transistor T2, a third transistor T3, a fourth transistor T4, a fifth transistor T5, a sixth transistor T6, a seventh transistor T7 and an eighth transistor T8.

The gate electrode of the first transistor T1 is coupled to the second scanning line S2, the first electrode of the first transistor T1 is coupled to the second electrode of the third transistor T3, and the second electrode of the first transistor T1 is coupled to the gate electrode T3-g of the third transistor T3;

The gate electrode of the second transistor T2 is coupled to the initialization control line R1, the first electrode of the second transistor T2 is coupled to the first initialization voltage line Vinit1, and the second electrode of the second transistor T2 is coupled to the gate electrode of the third transistor T3;

The gate electrode of the fourth transistor T4 is coupled to the first scanning line S1, the first electrode of the fourth transistor T4 is coupled to the data line D1, and the second electrode of the fourth transistor T4 is coupled to the first electrode of the third transistor T3;

The gate electrode of the fifth transistor T5 is coupled to the light emitting control line E1, the first electrode of the fifth transistor T5 is coupled to the first voltage line, and the second electrode of the fifth transistor T5 is coupled to the first electrode of the third transistor T3;

The gate electrode of the sixth transistor T6 is coupled to the light emitting control line E1, the first electrode of the sixth transistor T6 is coupled to the second electrode of the third transistor T3, and the second electrode of the sixth transistor T6 is coupled to the light emitting element.

The gate electrode of the seventh transistor T7 is coupled to the third scanning line S3, the first electrode of the seventh transistor T7 is coupled to the second initialization voltage line Vinit2, and the second electrode of the seventh transistor T7 is coupled to the light emitting element.

The gate electrode of the eighth transistor T8 is coupled to the third scanning line S3, the first electrode of the eighth transistor T8 is coupled to the reset voltage line DR, and the second electrode of the eighth transistor T8 is coupled to the first electrode of the third transistor T3.

The first transistor T1 and the second transistor T2 include N-type oxide transistors, and the first transistor T1 and the second transistor T2 need to be independently controlled by the second scanning line S2 and the initialization control line R1.

In the initialization phase P1, T2 is turned on, and the first initialization voltage line Vinit1 writes a lower negative voltage to the N1 node, that is, the first initialization voltage Vi1 (e.g. −3v), to initialize the gate electrode of the third transistor T3.

In the bias compensation phase P2, T8 is turned on, the reset voltage line DR writes a reset voltage (e.g. 5v) to the N2 node, and applies bias stress to the third transistor T3; at the same time, T7 is turned on, the second initialization voltage line Vinit2 writes the second initialization voltage Vi2 to the anode of the light emitting element to initialize the anode. It should be noted that the reset voltage may be a reference voltage Vref, and Vref is used to apply bias stress to the third transistor, and is usually a high voltage to achieve the effect.

In the writing-in compensation phase P3, T1 is turned on, and after T4 is turned on, the data signal is written to the N1 node to realize threshold voltage compensation.

After the writing-in compensation phase P3, after a short time interval, the light emitting phase P4 begins, and the screen starts to emit light.

The disadvantages of the above-mentioned pixel circuit are as follows:

The first disadvantage: at the moment tb, the second scanning signal written by the second scanning line S2 changes from a low level to a high level, and T1 is turned on. At this time, the Vref voltage on the N2 node and the N3 node will quickly pull up the N1 node, which causes that when the data signal starts to be written at the moment tc, the initial voltage of the N1 node that controls T3 to be turned on is no longer Vi1, but a higher voltage that changes with Vref, and the level of the N1 node controls T3 to be turned on or off (in a certain range, the lower the voltage of the N1 node is, the better the turning on of the T3 is, and the greater the current flowing through T3 is), that is, it affects the writing-in of the data signal Vdata, resulting in insufficient writing.

The second disadvantage: at the terminal of the writing-in compensation phase P3, the second scanning signal written by the second scanning line S2 changes from a high level to a low level, and the parasitic capacitance formed by T1 will couple and pull down the N1 node, As a result, the light emitting element becomes brighter, and the data voltage required to display a black screen needs to be higher.

The third disadvantage: at the moment tb, because the current timing is a GOA (S2) provides the second scanning signal for the second scanning line S2 corresponding to the two rows of sub-pixels at the same time; and the capacitance of the N2 node and N3 node in the two rows of sub-pixels may be different due to the different layout, so at the moment tb, the discharge amounts to the N1 node in the two rows of sub-pixels are different, which causes the initial voltage of the N1 node to be different before the data signal is written. Moreover, since the display substrate is scanned row-by-row during display, when one row of sub-pixels is scanned, the N1 node is given a voltage for a long time, resulting in the initial voltages of the N1 node in the two rows of sub-pixels before the data signal is written are different. Therefore, when the two rows of sub-pixels include an odd row of sub-pixels and an even row of sub-pixels, there will be a difference in display brightness of the odd row and even row of sub-pixels.

Based on the above three disadvantages, embodiments of the present disclosure provide the following technical solutions.

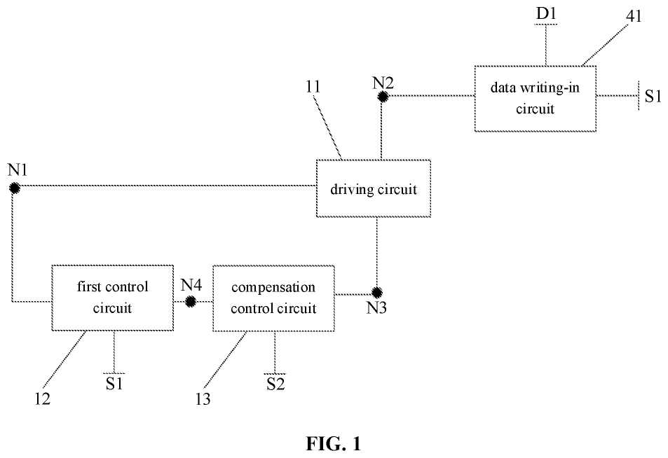

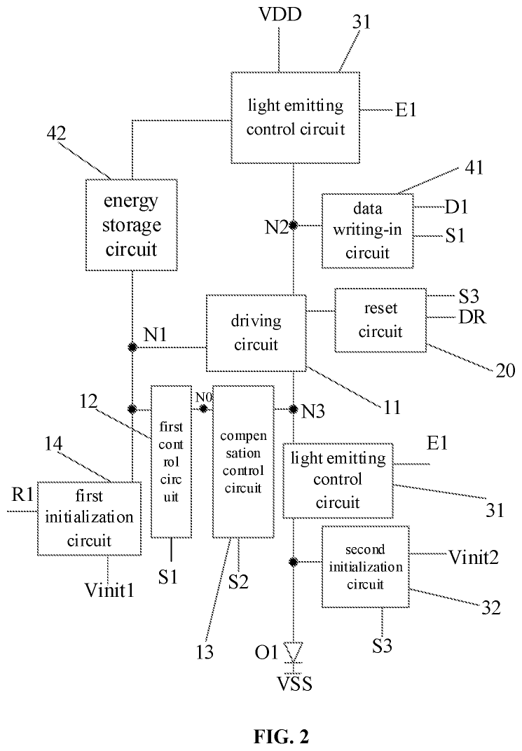

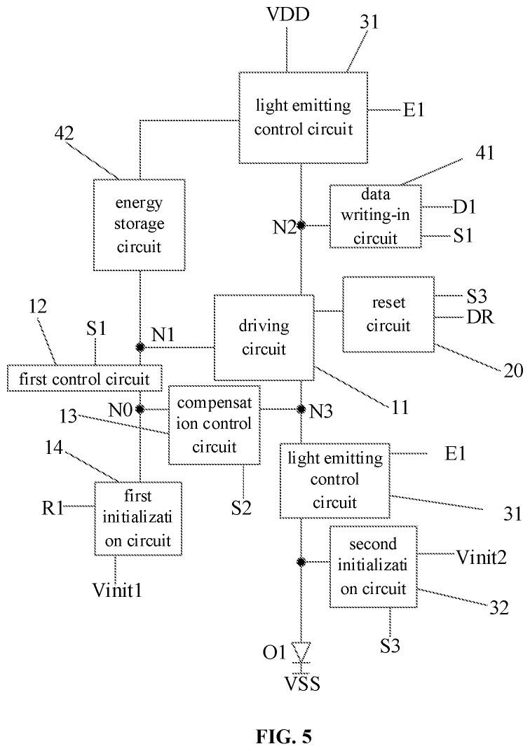

Please refer to FIG. 1, FIG. 2, and FIG. 5, an embodiment of the present disclosure provides a pixel circuit, including: a driving circuit 11, a data writing-in circuit 41, a compensation control circuit 13 and a first control circuit 12;

The data writing-in circuit 41 is respectively coupled to the first scanning line S1, the data line D1, and the second terminal of the driving circuit 11, and is used to control to connect the data line D1 and the second terminal of the driving circuit 11 (that is, the second node N2) under the control of the first scanning signal provided by the first scanning line S1;

The compensation control circuit 13 is respectively coupled to the second scanning line S2, the first terminal of the driving circuit 11 (that is, the third node N3) and the connection node N0, and is used to control to connect the first terminal of the driving circuit 11 and the connection node N0 under the control of the second scanning signal provided by the second scanning line S2;

The first control circuit 12 is respectively coupled to the first scanning line S1, the control terminal (first node N1) of the driving circuit 11 and the connection node N0, and is used to control to connect the control terminal of the driving circuit 11 and the connection node N0 under the control of the first scanning signal.

Exemplarily, the first scanning line S1 is configured to write the first scanning signal, and the data line D1 is configured to write data signal. The second scanning line S2 is configured to write the second scanning signal.

Exemplarily, when the first scanning signal is at an active level, the data writing-in circuit 41 is configured to control to electrically connect the data line D1 and the second terminals of the driving circuit 11 under the control of the first scanning signal provided by the first scanning line S1. When the first scanning signal is at an inactive level, the data writing-in circuit 41 is configured to disconnect the data line D1 from the second terminal of the driving circuit 11 under the control of the first scanning signal provided by the first scanning line S1.

Exemplarily, when the first scanning signal is at an active level, the first control circuit 12 is configured to electrically connect the control terminal of the driving circuit 11 and the connection node N0 under the control of the first scanning signal. When the first scanning signal is at an inactive level, the first control circuit 12 is configured to disconnect the control terminal of the driving circuit 11 and the connection node N0 under the control of the first scanning signal.

Exemplarily, when the second scanning signal is at an active level, the compensation control circuit 13 is configured to electrically connect the first terminal of the driving circuit 11 and the connection node N0 under the control of the second scanning signal; when the second scanning signal is at an inactive level, the compensation control circuit 13 is used to disconnect the first terminal of the driving circuit 11 from the connection nodes N0 under the control of the second scanning signal.

Exemplarily, the driving circuit 11 is used to control to connect the first terminal of the driving circuit 11 and the second terminal of the driving circuit 11 under the control of the potential of the control terminal thereof.

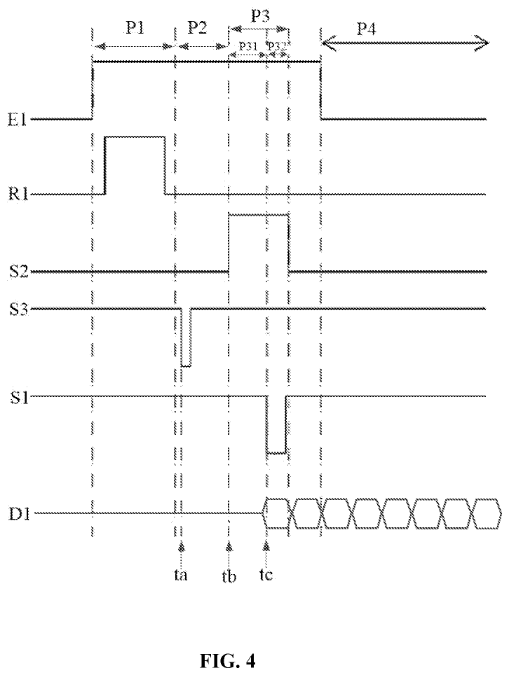

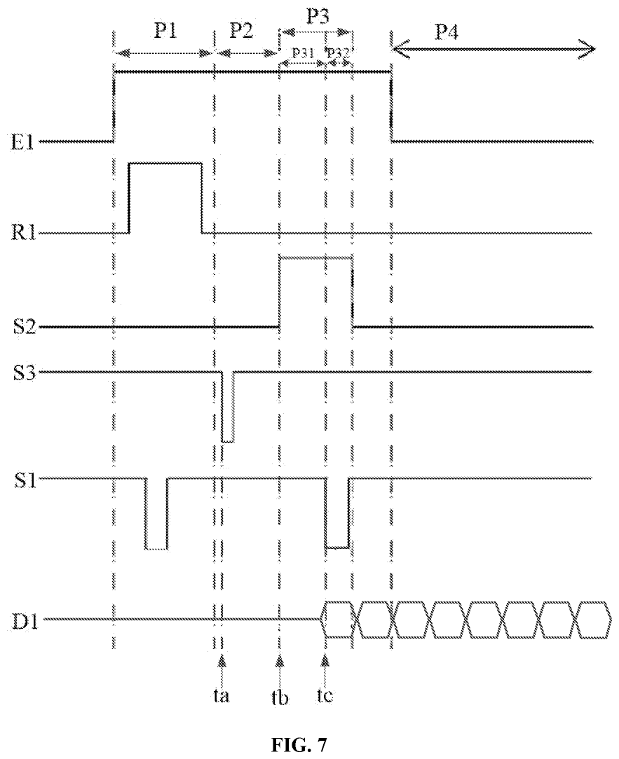

As shown in FIG. 4 and FIG. 7, exemplary, the display period includes a writing-in compensation phase P3, and the writing-in compensation phase P3 includes: a writing-in control phase P32 and a non-writing-in control phase P31; the driving method includes:

During the entire writing-in compensation phase P3, the compensation control circuit 13 controls to connect the first terminal of the driving circuit 11 and the connection node N0 under the control of the second scanning signal;

In the non-writing-in control phase P31, the data writing-in circuit 41 is configured to control to disconnect the data line D1 and the second terminal of the driving circuit 11 under the control of the first scanning signal; the first control circuit 12 is configured to control to disconnect the control terminal of the driving circuit 11 and the connection node N0 under the control of the first scanning signal;

In the writing-in control phase P32, the data writing-in circuit 41 controls to connect the data line D1 and the second terminal of the driving circuit 11 under the control of the first scanning signal; the first control circuit 12 is configured to control to connect the control terminal of the driving circuit 11 and the connection node N0 under the control of the first scanning signal.

According to the specific structure of the above-mentioned pixel circuit, in the pixel circuit provided by the embodiment of the present disclosure, the first control circuit 12 is connected between the N1 node and the compensation control circuit 13, and the first control circuit 12 and the data writing-in circuits 41 are all controlled by the first scanning signal, and the following beneficial effects are achieved.

Effect 1: At the moment tb, the second scanning signal written by the second scanning line S2 changes from a low level to a high level, and T1 is turned on. Between the moment tb and the moment tc, since the first control circuit 12 controls to disconnect the N1 node and the connection node N0, the voltages of the N2 node and the N3 node will no longer flow to the N1 node, which can ensure that when the data signal is written at the moment tc, the potential of the N1 node is still kept at the low voltage of Vi1, which ensures sufficient writing-in of the data signal.

Effect 2: At the end of the writing-in compensation phase P3, the second scanning signal written by the second scanning line S2 changes from a high level to a low level. By adding the first control circuit 12, at the end of the writing-in compensation phase P3, the first scanning signal written by the first scanning line S1 changes from the low level to the high level, so that at the end of the writing-in compensation phase P3, there is a process of pulling up N1 node, which is beneficial to reduce the data voltage required to display a black screen.

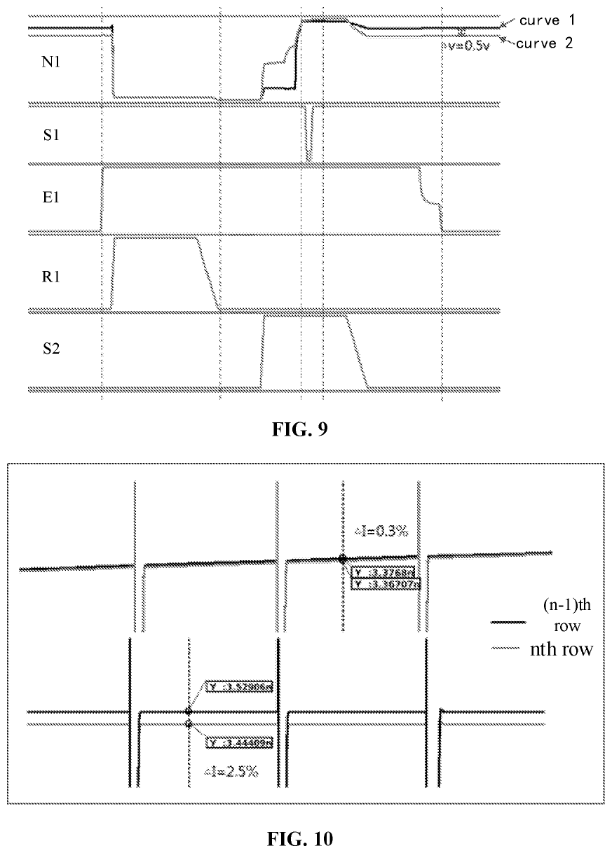

As shown in FIG. 9, curve 1 is a simulation curve of the potential of node N1 when the first control circuit 12 is provided in the pixel circuit. Curve 2 is a simulation curve of the potential of node N1 when the first control circuit 12 is not provided in the pixel circuit. Comparing curve 1 and curve 2, when the first control circuit 12 is set, the potential of the N1 node is increased by 0.5v, so it is estimated that the corresponding data voltage can be reduced by 0.5v when displaying a black picture, that is, the data voltage required for displaying the black picture is reduced.

Effect 3: In the case where one GOA (S2) simultaneously provides the second scanning signal to the second scanning line S2 corresponding to two rows of sub-pixels. At the moment tb, the second scanning signal written by the second scanning line S2 changes from a low level to a high level, and T1 is turned on. Between the moment tb and the moment tc, since the first control circuit 12 controls to disconnect the N1 node and the connection node N0, it will not discharge to the N1 node between the moment tb and the moment tc, thereby ensuring that the same initial voltage of the N1 node before the data signal is written is the same.

Moreover, between the moment tb and the moment tc, because the first control circuit 12 controls to disconnect the N1 node and the connection node N0, it is ensured that it is the same moment that the voltage applied to the N1 node in the two rows of sub-pixels, Therefore, even in the case of progressive scanning, the initial voltages of the N1 nodes in the two rows of sub-pixels before data signal is written are the same.

Therefore, when the two rows of sub-pixels include odd rows of sub-pixels and even rows of sub-pixels, there will be no difference in display brightness of the odd and even row of sub-pixels.

As shown in FIG. 10, it shows the difference in driving current of sub-pixels in odd and even rows under a certain data signal. It can be seen that the pixel circuit provided by the present disclosure basically eliminates the difference in driving current of sub-pixels in odd and even rows (the difference is 0.3%). When the sub-pixels use the pixel circuit without the first control circuit 12, the difference in driving current of the sub-pixels in the odd and even rows will reach 2.5% (the difference in driving current of the sub-pixels in the odd and even rows is required to be less than 2% in general specifications). It should be noted that the abscissa in FIG. 9 is time, and the ordinate is current.

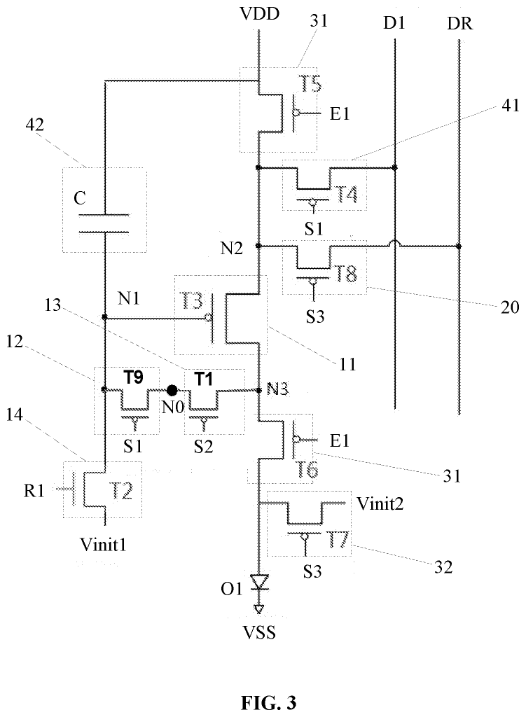

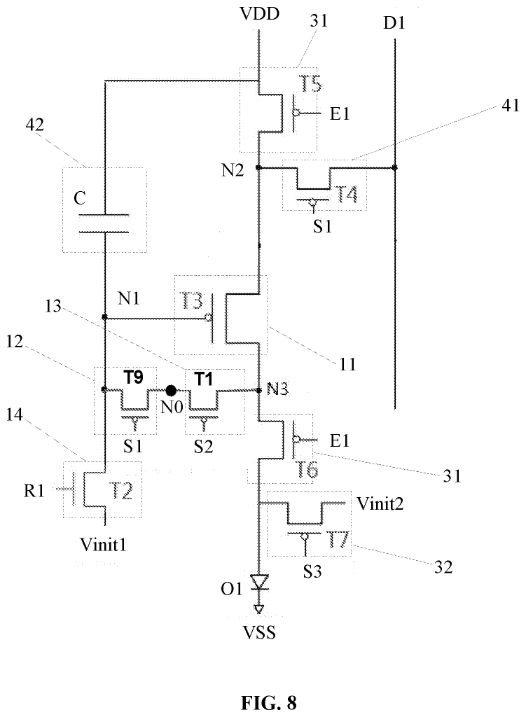

As shown in FIG. 2, FIG. 3 and FIG. 8, in some embodiments, the pixel circuit further includes:

a first initialization circuit 14, wherein the first initialization circuit 14 is respectively coupled to the initialization control line R1, the first initialization voltage line Vinit1 and the control terminal of the driving circuit 11, and is configured to control to connect the first initialization voltage line Vinit1 and the control terminal of the driving circuit 11 under the control of the initialization control signal provided by the initialization control line R1.

The display period also includes an initialization phase; the driving method includes:

In the initialization phase, controlling, by the first initialization circuit 14 in the pixel circuit, to connect the first initialization voltage line Vinit1 and the control terminal of the driving circuit 11 under the control of the initialization control signal, so as to realize the initialization of the control terminal of the driving circuit 11.

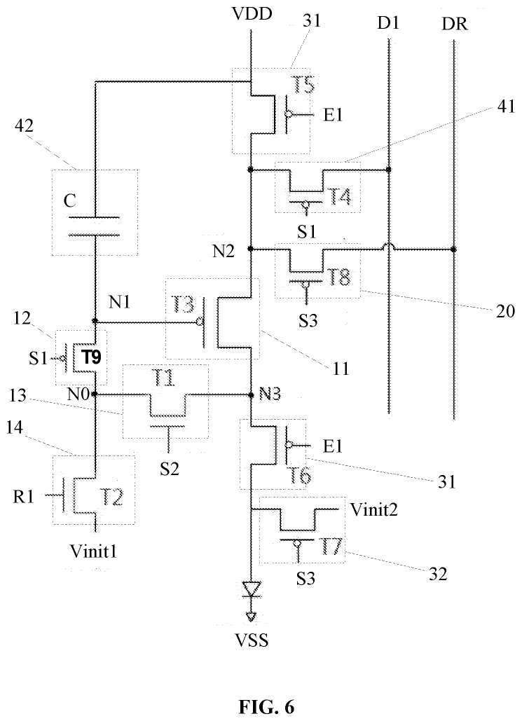

As shown in FIGS. 5 to 7, in some embodiments, the pixel circuit further includes:

a first initialization circuit 14, wherein the first initialization circuit 14 is respectively coupled to the initialization control line R1, the first initialization voltage line Vinit1 and the connection node N0, and is configured to control to connect the first initialization voltage line Vinit1 and the connection node N0 under the control of the initialization control signal provided by the initialization control line R1.

The display period also includes an initialization phase; the driving method includes:

In the initialization phase, controlling, by the first initialization circuit 14, to connect the first initialization voltage line Vinit1 and the connection node N0 under the control of the initialization control signal, and controlling, by the first control circuit 12, to connect the control terminal of the driving circuit 11 and the connection node N0 under the control of the first scanning signal, so as to realize the initialization of the control terminal of the driving circuit 11.

Both of the above two connection modes of the first initialization circuit 14 and the corresponding specific driving methods can realize the initialization of the control terminal of the driving circuit 11.

As shown in FIGS. 2 to 8, in some embodiments, the pixel circuit further includes:

A reset circuit 20, wherein the reset circuit 20 is respectively coupled to the third scanning line S3, the reset voltage line DR and the second terminal of the driving circuit 11, is configured to control to connect the reset voltage line DR and the second terminal of the driving circuit 11 under the control of the third scanning signal provided by the third scanning line S3.

In some embodiments, the pixel circuit also includes:

A reset circuit, wherein the reset circuit is respectively coupled to the third scanning line, the reset voltage line and the first terminal of the driving circuit, and is configured to control to connect the reset voltage line and the first terminal of the driving circuit under the control of the third scanning signal provided by the third scanning line.

Exemplarily, the reset voltage line DR is used to provide a reset voltage.

Exemplarily, the data signal is used for normal display. The reset voltage can follow the change of the data signal, and in the bias compensation phase P2, a bias voltage opposite in sign to that in the light emitting phase P4 is applied to the driving transistor included in the driving circuit 11, for example: the bias voltage Vgs of the driving transistor in the light emitting phase P4 (or Vgd) is 5V, and the bias voltage of the driving transistor is −5V through the reset voltage line DR in the compensation phase.

Exemplarily, when the third scanning signal is at an active level, the reset circuit 20 is configured to electrically connect the reset voltage line DR and the second terminal or the first terminal of the driving circuit 11 under the control of the third scanning signal. When the third scanning signal is at an inactive level, the reset circuit 20 is configured to disconnect the reset voltage line DR from the second terminal or the first terminal of the driving circuit 11 under the control of the third scanning signal.

Exemplarily, one display period in which the pixel circuit works includes: a writing-in compensation phase P3 and a bias voltage compensation phase P2.

In the writing-in compensation phase P3, the data writing-in circuit 41 controls to connect the data line D1 and the second terminal of the driving circuit 11 under the control of the first scanning signal, and writes the data signal to the second terminal of the driving circuit 11.

In the bias compensation phase P2, the reset circuit 20 controls to connect the reset voltage line DR and the second terminal of the driving circuit 11 under the control of the third scanning signal; or the reset circuit 20 controls to connect the reset voltage line DR and the first terminal of the driving circuit 11; so as to write the reset voltage into the first terminal or the second terminal of the driving circuit 11.

In the pixel circuit provided by the above-mentioned embodiments, by setting the reset circuit 20, a bias voltage opposite in sign to that in the light emitting phase P4 can be applied to the driving circuit 11 in the bias compensation phase P2, thereby compensating the characteristics shift of the driving circuit 11 after it works at a certain bias voltage for a period of time, improving problems such as short-term afterimage and slow response time. Moreover, when driving at low frequency, it can compensate the difference in brightness caused by the characteristic deviation of the driving circuit 11 in the light emitting period for a long time, and improve the flicker phenomenon.

In addition, when the pixel circuits provided by the above embodiments are applied to a display substrate, specific bias compensation can be implemented for the driving circuit 11 in each pixel circuit in the display substrate, which has a good compensation effect.

In addition, since the reset voltage provided by the reset voltage line DR can be adjusted independently, it can provide an appropriate bias voltage to each pixel circuit in the display substrate as required.

In the pixel circuit provided by the above embodiment, due to the addition of the first control circuit 12, at the moment tb, even if the second scanning signal is at an active level, it will not affect the potential of the N1 node. Therefore, the moment tc is moved backward, the length between the moment ta and the moment tc is increased to increase the time for applying bias stress to the driving circuit, which is beneficial to further improve the afterimage caused by hysteresis.

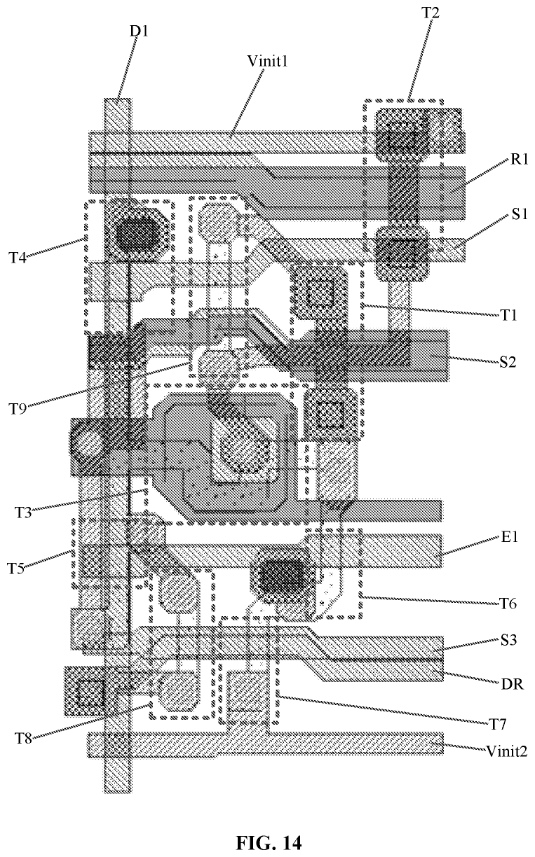

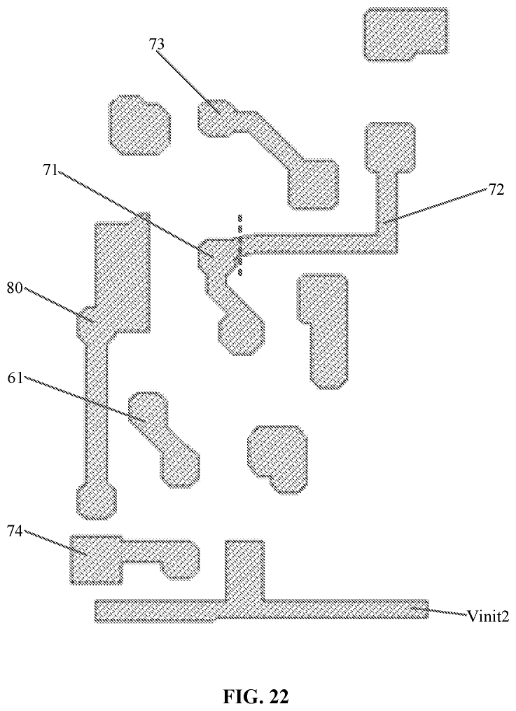

As shown in FIG. 2 to FIG. 8, FIG. 14 and FIG. 22, in some embodiments, the pixel circuit further includes: a light emitting control circuit 31, an energy storage circuit 42 and a light emitting element O1;

The light emitting control circuit 31 is respectively coupled to the light emitting control line E1, the first terminal of the driving circuit 11 and the light emitting element O1, and is used to control to connect the first terminal of the driving circuit 11 and the light emitting element O1 under the control of the light emitting control signal provided by the light emitting control line E1;

The light emitting control circuit 31 is also coupled to the first voltage line 80 and the second terminal of the driving circuit 11, and is used to control to connect the first voltage line 80 and the second terminal of the driving circuit 11 under the control of the light emitting control signal;

The energy storage circuit 42 is respectively coupled to the control terminal of the driving circuit 11 and the first voltage line 80.

Exemplarily, each display period in which the pixel circuit works includes: an initialization phase P1, a bias compensation phase P2, a writing-in compensation phase P3 and a light emitting phase P4.

In more detail, after the writing-in compensation phase P3, the gate potential of the driving transistor becomes Vdata+Vth, where Vdata is the data voltage corresponding to the data signal, and Vth is the threshold voltage of the driving transistor. After entering the light emitting phase P4, the voltage applied to the driving transistor is Vgs1=Vdata+Vth−VDD, VDD is the power supply voltage received by the driving transistor and provided by the first voltage line.

In the bias compensation phase P2, the reset circuit 20 writes a reset voltage V1 to the first terminal or the second terminal of the driving circuit 11. The reset voltage makes the driving transistor receive a bias voltage of Vgs2, and Vgs2 satisfies: Vgs2=−Vgs1.

Namely: Vgs2=Vdata+Vth−V1=−Vgs1=−(Vdata+Vth−VDD)

It should be noted that when entering the bias compensation phase P2, the gate voltage Vg of the driving transistor remains unchanged.

V1=2*(Vdata+Vth)−VDD

Since VDD is a fixed value, Vth can be obtained through testing, so the value relationship between V1 and Vdata can be obtained. V1 is set according to the above relationship, and the best compensation effect can be achieved.

In the bias compensation phase P2, since the driving transistor receives a bias voltage of the same magnitude and opposite direction as that in the light emitting phase P4, bias compensation can be realized.

As shown in FIG. 2 to FIG. 8, in some embodiments, the pixel circuit further includes: a second initialization circuit 32 and a light emitting element O1;

The second initialization circuit 32 is respectively coupled to the third scanning line S3, the second initialization voltage line Vinit2 and the light emitting element O1, and is configured to control to connect the second initialization voltage line Vinit2 and the light emitting element O1 under the control of the third scanning signal provided by the third scanning line S3.

Exemplarily, the second initialization voltage line Vinit2 is used to provide the second initialization voltage Vi2.

The second initialization circuit 32 can reset the first electrode of the light emitting element O1 under the control of the third scanning signal.

It should be noted that the first electrode of the light emitting element O1 includes an anode, and the second electrode (i.e., cathode) of the light emitting element O1 receives a negative power supply signal VSS.

In some embodiments, the pixel circuit further includes a first initialization circuit 14, the first initialization circuit 14 is coupled to a first initialization voltage line Vinit1, and the first initialization voltage line Vinit1 is multiplexed as the reset voltage line dr.

Exemplarily, the reset circuit 20 is coupled to the first initialization voltage line Vinit1. The first initialization voltage Vi1 provided by the first initialization voltage line Vinit1 is adjustable.

Exemplarily, the first initialization voltage Vi1 provided by the first initialization voltage line Vinit1 is variable. Exemplarily, when the first initialization voltage Vi1 is used to initialize the gate electrode of the driving transistor, it can be set to −5V, and when the first initialization voltage Vi1 is used for bias compensation, it can be set to 5V.

The first initialization voltage line Vinit1 being multiplexed as the reset voltage line DR can simplify the sub-pixel structure, reduce the layout difficulty of the sub-pixels, and improve the resolution of the display substrate.

As shown in FIGS. 2 to 8, in some embodiments, the compensation control circuit 13 includes a first transistor T1, the driving circuit 11 includes a third transistor T3 (i.e., a driving transistor), and the data writing-in circuit 41 includes a fourth transistor T4, the first control circuit 12 includes a ninth transistor T9;

The gate electrode of the first transistor T1 is coupled to the second scanning line S2, the first electrode of the first transistor T1 is coupled to the second electrode of the third transistor T3, and the second electrode of the first transistor T1 is coupled to the connection node NO;

The gate electrode of the fourth transistor T4 is coupled to the first scanning line S1, the first electrode of the fourth transistor T4 is coupled to the data line D1, and the second electrode of the fourth transistor T4 is coupled to the first electrode of the third transistor T3;

The gate electrode of the ninth transistor T9 is coupled to the first scanning line S1, the first electrode of the ninth transistor T9 is coupled to the connection node N0, and the second electrode of the ninth transistor T9 is coupled to the gate electrode of the third transistor T3.

In some embodiments, the first initialization circuit 14 includes a second transistor T2, the gate electrode of the second transistor T2 is coupled to the initialization control line R1, and the first electrode of the second transistor T2 is connected to the first initialization voltage line Vinit1, and the second electrode of the second transistor T2 is coupled to the control terminal of the driving circuit 11.

In some embodiments, the first initialization circuit 14 includes a second transistor T2, the gate electrode of the second transistor T2 is coupled to the initialization control line R1, and the first electrode of the second transistor T2 is connected to the first initialization voltage line Vinit1, and the second electrode of the second transistor T2 is coupled to the connection node N0.

In some embodiments, the reset circuit 20 includes an eighth transistor T8;

The gate electrode of the eighth transistor T8 is coupled to the third scanning line S3, the first electrode of the eighth transistor T8 is coupled to the reset voltage line DR, and the second electrode of the eighth transistor T8 is coupled to the second terminal of the driving circuit 11.

In some embodiments, the reset circuit 20 includes an eighth transistor T8;

The gate electrode of the eighth transistor T8 is coupled to the third scanning line S3, the first electrode of the eighth transistor T8 is coupled to the reset voltage line DR, and the second electrode of the eighth transistor T8 is coupled to the first terminal of the driving circuit 11.

In some embodiments, the light emitting control circuit 31 includes a fifth transistor T5 and a sixth transistor T6;

The gate electrode of the fifth transistor T5 is coupled to the light emitting control line E1, the first electrode of the fifth transistor T5 is coupled to the first voltage line 80, and the second electrode of the fifth transistor T5 is coupled to the second terminal of the driving circuit 11;

The gate electrode of the sixth transistor T6 is coupled to the light emitting control line E1, the first electrode of the sixth transistor T6 is coupled to one terminal of the driving circuit 11, and the second electrode of the sixth transistor T6 is coupled to the light emitting element O1.

In some embodiments, the second initialization circuit 32 includes a seventh transistor T7,

The gate electrode of the seventh transistor T7 is coupled to the third scanning line S3, the first electrode of the seventh transistor T7 is coupled to the second initialization voltage line Vinit2, and the second electrode of the seventh transistor T7 is coupled to the light emitting element O1.

In some embodiments, the first transistor T1 and the second transistor T2 are oxide thin film transistors.

By setting the first transistor T1 and the second transistor T2 as oxide thin film transistors, it is beneficial to reduce the current leakage of the gate electrode of the driving transistor and ensure the stability of the gate potential of the driving transistor.

Exemplarily, in at least one embodiment of the pixel circuit, T1 and T2 may be oxide thin film transistors, T3, T4, T5, T6, T7, T8 and T9 may all be low temperature polysilicon thin film transistors, T1 and T2 are n-type transistors, T3, T4, T5, T6, T7, T8 and T9 are p-type transistors, but not limited thereto.

Exemplarily, T1 and T2 may be single-gate transistors or a double-gate transistor.

Exemplarily, in the width-to-length ratio W/L of the channel of T1, the value range of W is between 2 microns and 4 microns, which may include the endpoint value, and the value range of L is between 3 microns and 6 microns, which may include the endpoint value.

Exemplarily, the width-to-length ratios of channels of T2 and T1 are the same.

Exemplarily, in the width-to-length ratio W/L of the channel of T8, the value range of W is between 2 microns and 3 microns, which may include the endpoint value, and the value range of L is between 3.2 microns and 6 microns, which may include the endpoint value.

In some embodiments, the compensation control circuit 13 includes a first transistor T1, the first initialization circuit 14 includes a second transistor T2, and the driving circuit 11 includes a third transistor T3 (i.e., the driving transistor), the light emitting control circuit 31 includes a fifth transistor T5 and a sixth transistor T6;

The gate electrode of the first transistor T1 is coupled to the second scanning line S2, the first electrode of the first transistor T1 is coupled to the second electrode of the third transistor T3, and the second electrode of the first transistor T1 is coupled to the gate electrode T3-g of the third transistor T3;

The gate electrode of the second transistor T2 is coupled to the initialization control line R1, the first electrode of the second transistor T2 is coupled to the first initialization voltage line Vinit1, and the second electrode of the second transistor T2 is coupled to the gate electrode T3-g of the third transistor T3;

The gate electrode of the fifth transistor T5 is coupled to the light emitting control line E1, the first electrode of the fifth transistor T5 is coupled to the first voltage line, and the second electrode of the fifth transistor T5 is coupled to the first electrode of the third transistor T3;

The gate electrode of the sixth transistor T6 is coupled to the light emitting control line E1, the first electrode of the sixth transistor T6 is coupled to the second electrode of the third transistor T3, and the gate electrode of the sixth transistor T6 is coupled to the light emitting element O1.

In some embodiments, the gate electrode of the seventh transistor T7 is coupled to the third scanning line S3, the first electrode of the seventh transistor T7 is coupled to the second initialization voltage line Vinit2, the second electrode of the seventh transistor T7 is coupled to the light emitting element O1.

In some embodiments, the gate electrode of the fourth transistor T4 is coupled to the first scanning line S1, the first electrode of the fourth transistor T4 is coupled to the data line D1, and the second electrode of the fourth transistor T4 is coupled to the first electrode of the third transistor T3;

The gate electrode T8-g of the eighth transistor T8 is coupled to the third scanning line S3, the first electrode of the eighth transistor T8 is coupled to the reset voltage line DR, and the second electrode of the eighth transistor T8 is coupled to the first electrode or the second electrode of the third transistor T3.

In some embodiments, the gate electrode of the ninth transistor T9 is coupled to the first scanning line S1, the first electrode of the ninth transistor T9 is coupled to the connection node N0, and the second electrode of the ninth transistor T9 is coupled to the gate electrode T3-g of the third transistor T3.

The specific driving process of the pixel circuit with the above structure includes:

In the initialization phase P1, R1 provides a high voltage signal and T2 is turned on. S1 provides a high voltage signal, T4 and T9 are turned off. S2 provides a low voltage signal and T1 is turned off. S3 provides a high voltage signal, T7 and T8 are turned off. The initialization of the gate electrode of T3 is implemented in the initialization phase P1, so that T3 can be turned on when the writing-in compensation phase P3 starts.

In the bias compensation period P2, R1 provides a low voltage signal, and T2 is turned off. S1 provides a high voltage signal, T4 and T9 are turned off. S2 provides a low voltage signal and T1 is turned off. S3 provides a low voltage signal, and T7 and T8 are turned on. In the bias compensation period P2, the reset voltage provided by DR can be written into the first electrode or the second electrode of the third transistor T3, and the second initialization voltage can be written into the anode of O1, so that O1 does not emit light, and the residual charge on the anode of O1 is cleared.

In the writing-in compensation phase P3, T3 is turned on. R1 provides a low voltage signal and T2 is turned off. S1 provides a low voltage signal, T4 and T9 are turned on. S2 provides a high voltage signal and T1 is turned on. S3 provides a high voltage signal, T7 and T8 are turned off. The data voltage Vdata on the data line D1 is written into the first electrode of the third transistor T3. In the writing-in compensation phase P3, Vdata is used to charge C through the turned-on T4, T3, T1 and T9 to increase the potential of the gate electrode of T3 until T3 is turned off. At this time, the potential of the gate electrode of T3 is Vdata+Vth.

In the light emitting phase P4, E1 provides a low-voltage signal, R1 provides a low-voltage signal, S1 provides a high-voltage signal, S2 provides a low-voltage signal, S3 provides a high-voltage signal, T1, T2, T4, T9, T7 and T8 are turned off, and T5 And T6 are turned on, and T3 is turned on to drive O1 to emit light.

By adding T8 to provide bias voltage for the first or second electrode of T3, it is beneficial to improve the stability of T3; by setting T7, the potential of the anode of O1 is initialized, which is beneficial to the freedom of on-off frequency switching under low-frequency flickering.

In some embodiments, the pixel circuit needs to turn on T3 in the threshold compensation phase, therefore, the voltage difference Vi1−V1 between the first initialization voltage Vi1 provided by the first initialization voltage line Vinit1 and the reset voltage V1 provided by the reset voltage line DR needs to be less than the threshold voltage Vth of the driving transistor T3. Wherein, Vi1 can be −2,¬−6V, for example, −2V, −3V, −4V, −5V, −6V and so on. Vi1−V1 can be less than a*Vth, a can be 2¬7, for example, a can be 2, 4, 6, 7; Vth can be −2,¬−5V, such as −2V, −3V, −5V, etc. V1 may be greater than 1.5 times of Vth, for example, V1 may be 1.6 times, 1.8 times, 2 times, etc. of Vth.

Exemplarily, V1 is greater than 0. The value of V1 is between 4 and 10V, which may include the endpoint value.

In some embodiments, the width-to-length ratio W/L of T8 may be approximately equal to the width-to-length ratio W/L of T7; for another example, the width-to-length ratio W/L of T8 may be greater than the width-to-length ratio W/L of T7, that is the width-to-length ratio W/L of T8 can be slightly larger, so that the N2 node can be quickly reset.

In some embodiments, the channel width W of T8 is 1.5-3.5, such as 1.6, 1.8, 1.9, 2.0, 2.2, 2.5, 3.0, etc.; the channel length L is 2.0-4.5; for example, it may be 2.5, 2.7, 3.0, 3.2, 3.5, 4.0, etc.; the channel width W of T7 is 1.5-3.5, such as 1.6, 1.8, 1.9, 2.0, 2.2, 2.5, 3.0, etc.; the channel length L is 2.0-4.5, such as 2.5, 2.7, 3.0, 3.2, 3.5, 4.0, etc.

In some embodiments, the width-to-length ratio W/L of T8 may be approximately equal to the width-to-length ratio W/L of T2; for another example, the width-to-length ratio W/L of T8 may be smaller than the width-to-length ratio W/L of T2, so as to balance the reset capabilities of N1 nodes and N2 nodes.

In some embodiments, the channel width W of T8 is 1.5-3.5, such as 1.6, 1.8, 1.9, 2.0, 2.2, 2.5, 3.0, etc.; the channel length L is 2.0-4.5; for example, it may be 2.5, 2.7, 3.0, 3.2, 3.5, 4.0, etc.; the channel width W of T2 is 1.5-3.5, such as 1.6, 1.8, 1.9, 2.0, 2.2, 2.5, 3.0, etc.; the channel length L is 2.0-4.5; for example, it can be 2.5, 2.7, 3.0, 3.2, 3.5, 4.0, etc.

The embodiment of the present disclosure also provides a driving method, which is applied to the pixel circuit provided in the above embodiment. The display period includes a writing-in compensation phase P3, and the writing-in compensation phase P3 includes: a writing-in control phase P32 and a non-writing-in control phase P31; the driving method includes:

In the entire writing-in compensation phase P3, the compensation control circuit 13 controls to connect the first terminal of the driving circuit 11 and the connection node N0 under the control of the second scanning signal;

In the non-writing-in control phase P31, the data writing-in circuit 41 is configured to control to not connect the data line D1 and the second terminal of the driving circuit 11 under the control of the first scanning signal; control to not connect the control terminal of the driving circuit 11 and the connection node N0 under the control of the first scanning signal;

In the writing-in control phase P32, the data writing-in circuit 41 controls to connect the data line D1 and the second terminal of the driving circuit 11 under the control of the first scanning signal; controls to connect the control terminal of the driving circuit 11 and the connection node N0 under the control of the first scanning signal.

When the pixel circuit is driven by the driving method provided by the embodiment of the present disclosure, the first control circuit 12 is connected between the N1 node and the compensation control circuit 13, and the first control circuit 12 and the data writing-in circuit 41 are all controlled by the first scanning signal, which achieves the following beneficial effects.

Effect 1: At the moment tb, the second scanning signal written by the second scanning line S2 changes from a low level to a high level, and T1 is turned on. Between the moment tb and the moment tc, since the first control circuit 12 controls to disconnect the N1 node and the connection node N0, the voltages of the N2 node and the N3 node will no longer flow to the N1 node, which can ensure that when the data signal is written at the moment tc, the potential of the N1 node is still kept at the low voltage of Vi1, which ensures sufficient writing-in of the data signal.

Effect 2: At the end of the writing-in compensation phase P3, the second scanning signal written by the second scanning line S2 changes from a high level to a low level. By adding the first control circuit 12, at the end of the writing-in compensation phase P3, the first scanning signal written by the first scanning line S1 changes from the low level to the high level, so that at the end of the writing-in compensation phase P3, there is a process of pulling up N1 node, which is beneficial to reduce the data voltage required to display a black screen.

Effect 3: In the case where one GOA (S2) simultaneously provides the second scanning signal to the second scanning line S2 corresponding to two rows of sub-pixels. At the moment tb, the second scanning signal written by the second scanning line S2 changes from a low level to a high level, and T1 is turned on. Between the moment tb and the moment tc, since the first control circuit 12 controls to disconnect the N1 node and the connection node N0, it will not discharge to the N1 node between the moment tb and the moment tc, thereby ensuring that the same initial voltage of the N1 node before the data signal is written is the same.

Moreover, between the moment tb and the moment tc, because the first control circuit 12 controls to disconnect the electrical connection between the N1 node and the connection node N0, it is ensured that the voltage applied to the N1 node in the two rows of sub-pixels is the same. Therefore, even in the case of progressive scanning, the initial voltages of the N1 nodes in the two rows of sub-pixels before data signal writing-in are the same.

Therefore, when the two rows of sub-pixels include odd rows of sub-pixels and even rows of sub-pixels, there will be no difference in display brightness of the odd and even row of sub-pixels.

In some embodiments, the end time of the writing-in compensation phase P3 is the same as the end time of the writing-in control phase P2.

Due to the addition of the first control circuit 12, at the moment tb, even if the second scanning signal is at an active level, it will not affect the potential of the N1 node, therefore, the moment tc can be moved backward, that is, the end time of writing-in compensation phase P3 is the same as the end time of the writing-in control phase P2, thereby increasing the length between the moment ta and the moment Tc, so as to increase the time for applying bias stress to the driving circuit, which is beneficial to further improve afterimage caused by hysteresis, etc.

Exemplarily, the time is move backward by 0.2 microseconds to 0.5 microseconds, and may include the endpoint value.

In some embodiments, the display period also includes an initialization phase; the driving method further includes:
The first initialization circuit 14 is respectively coupled to the initialization control line R1, the first initialization voltage line Vinit1 and the control terminal of the driving circuit 11, is configured to control to connect the first initialization voltage line Vinit1 and the control terminal of the driving circuit 11 under the control of the initialization control signal provided by the initialization control line R1. In the initialization phase, the first initialization circuit 14 in the pixel circuit controls to connect the first initialization voltage line Vinit1 and the control terminal of the driving circuit 11 under the control of the initialization control signal;
Alternatively, the first initialization circuit 14 is respectively coupled to the initialization control line R1, the first initialization voltage line Vinit1 and the connection node N0, and is configured to control to connect the first initialization voltage line Vinit1 and the connection node N0 under the control of the initialization control signal provided by the initialization control line R1. In the initialization phase, the first initialization circuit 14 controls to connect the first initialization voltage line Vinit1 and the connection node N0 under the control of the initialization control signal, and the first control circuit 12 is configured to control to connect the control terminal of the driving circuit 11 and the connection node N0 under the control of the first scanning signal.

Both of the above two connection modes of the first initialization circuit 14 and the corresponding specific driving methods can realize the initialization of the control terminal of the driving circuit 11.

In some embodiments, the display period further includes a bias compensation phase and a light emitting phase, and the driving method includes:

In the bias compensation phase, the reset circuit 20 controls to connect the reset voltage line DR and the second terminal of the driving circuit 11 under the control of the third scanning signal; or controls to connect the reset voltage line DR and the first terminal of the driving circuit 11;

In the light emitting phase, the light emitting control circuit 31 in the pixel circuit controls to connect the first voltage line 80 and the second terminal of the driving circuit 11 under the control of the light emitting control signal, and controls to connect the first terminal of the driving circuit 11 and the light emitting element O1, and the driving circuit 11 drives the light emitting element O1 to emit light.

When the pixel circuit is driven by the driving method provided by the embodiment of the present disclosure, a bias voltage opposite in sign to that in the light emitting phase P4 can be applied to the driving circuit 11 in the bias compensation phase P2, so as to compensate the characteristics deviation of the driving circuit 11 after it works at a certain bias voltage for a period of time, the problems such as short-term afterimage and slow response time are improved. Moreover, when driving at low frequency, it can compensate the difference in brightness caused by the characteristic deviation of the driving circuit 11 in the light emitting period for a long time, and improve the flicker phenomenon. In addition, specific bias compensation can be implemented for the driving circuit 11 in each pixel circuit in the display substrate, and has a good compensation effect. In addition, since the reset voltage provided by the reset voltage line DR can be adjusted independently, it can provide an appropriate bias voltage to each pixel circuit in the display substrate as required.

More specifically, in the initialization phase P1, the first initialization circuit 14 controls to connect the first initialization voltage line Vinit1 and the control terminal of the driving circuit 11 to initialize the control terminal of the driving circuit 11. In the bias compensation phase P2, the reset circuit 20 controls to connect the reset voltage line DR and the second terminal of the driving circuit 11, or controls to connect the reset voltage line DR and the first terminal of the driving circuit 11. In the light emitting phase P4, the light emitting control circuit 31 controls to connect the first voltage line and the second terminal of the driving circuit 11, and controls to connect the first terminal of the driving circuit 11 and the light emitting element O1, the driving circuit 11 drives the light emitting element O1 to emit light.

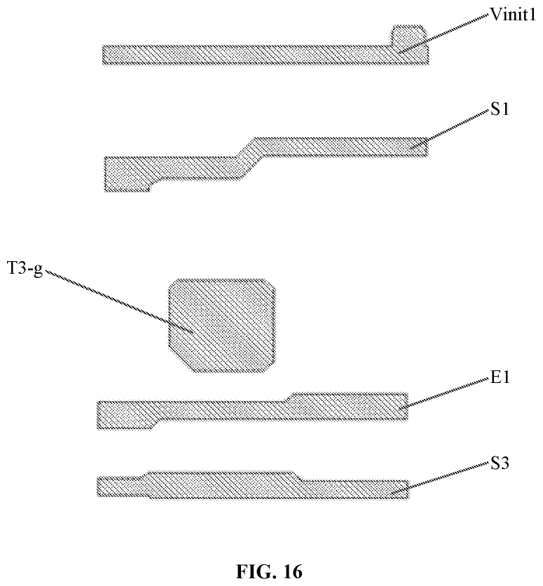

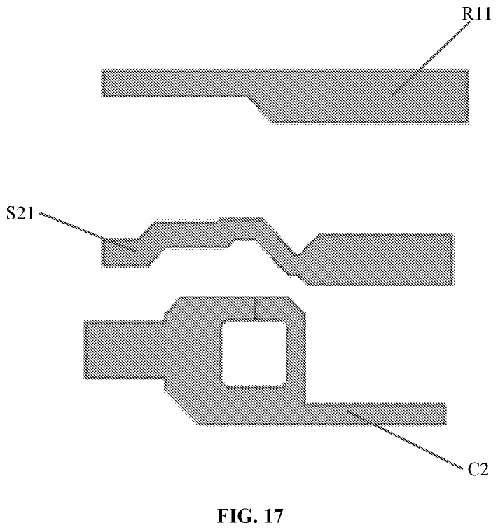

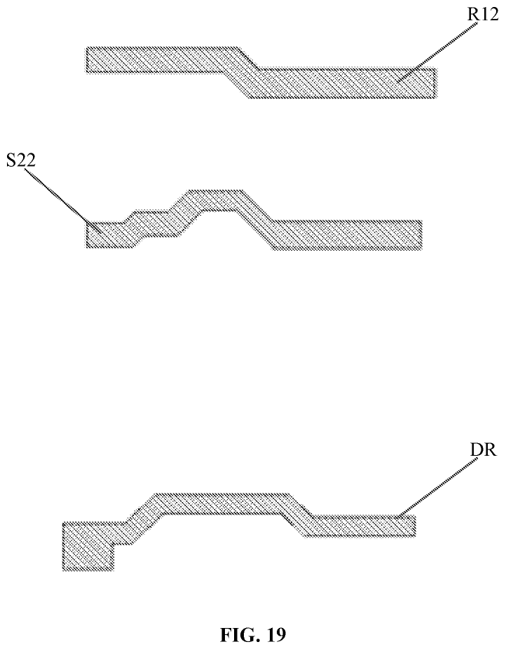

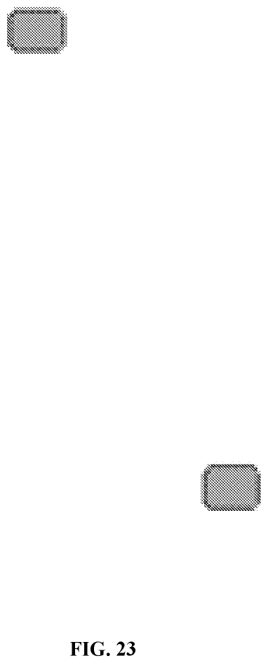

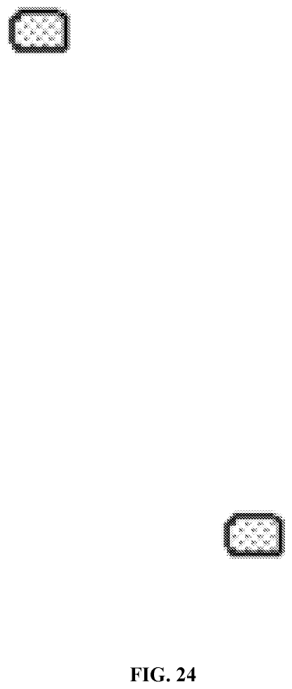

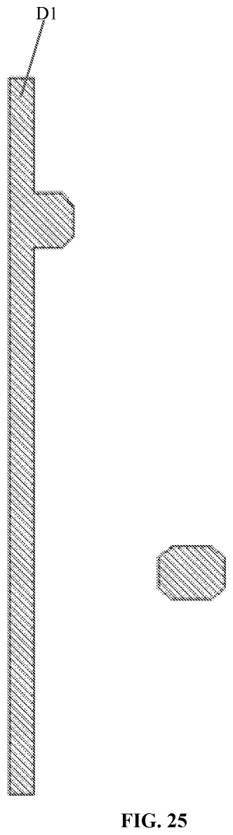

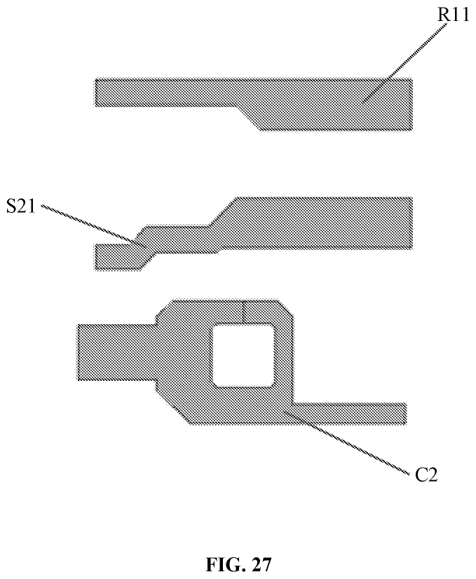

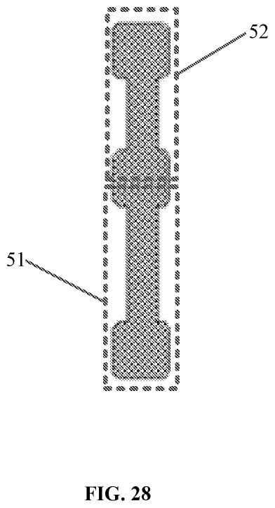

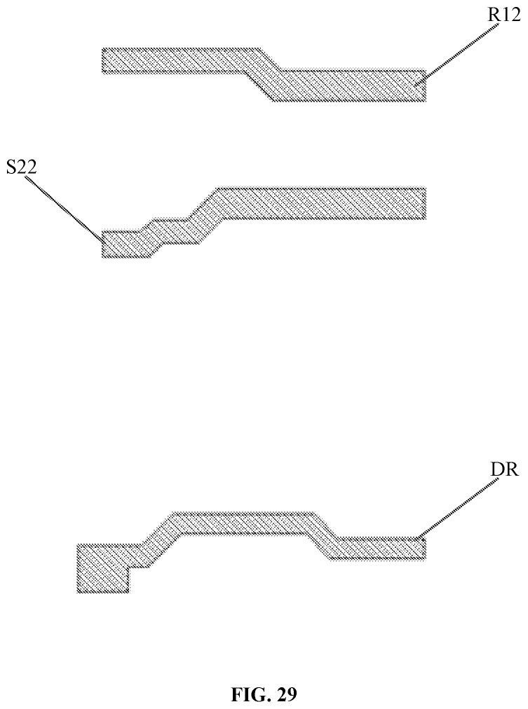

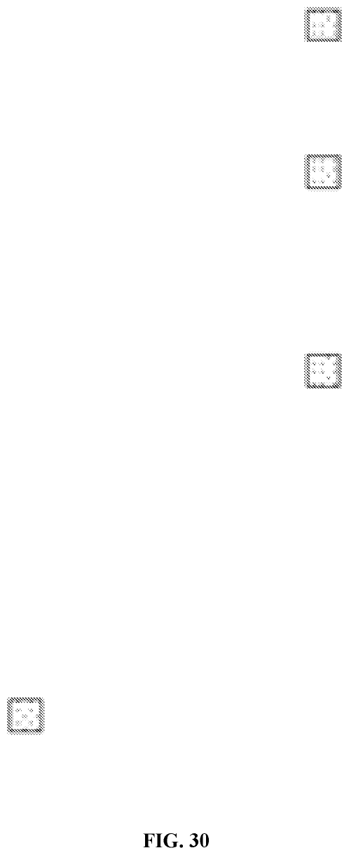

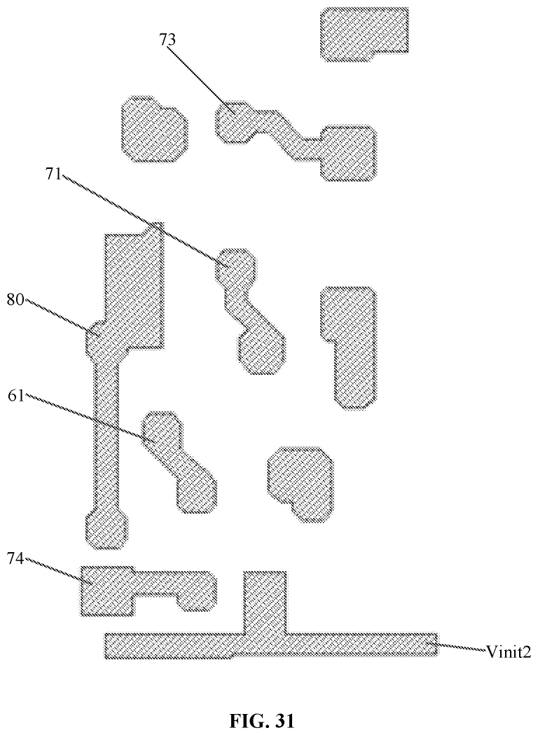

As shown in FIG. 3 to FIG. 8 and FIG. 14 to FIG. 35, the embodiment of the present disclosure also provides a display substrate, including abase substrate and a plurality of sub-pixels arranged on the base substrate, and the sub-pixels include the pixel circuit provided in the above-mentioned embodiments; the sub-pixel also includes:

A data line D1, a first scanning line S1 and a second scanning line S2; wherein the data line D1 includes at least a portion extending along a first direction, the first scanning line S1 includes at least a portion extending along a second direction, the third scanning line S3 includes at least a portion extending along the second direction, the second direction intersects the first direction;

a data writing-in circuit 41, respectively coupled to the first scanning line S1, the data line D1 and the second terminal of the driving circuit 11, configured to control to connect the data line D1 and the second terminal of the driving circuit 11 under the control of the first scanning signal provided by the first scanning line S1;

a compensation control circuit 13, respectively coupled to the second scanning line S2, the first terminal of the driving circuit 11 and the connection node N0, configured to control to connect the first terminal of the driving circuit 11 and the connection node N0 under the control of the second scanning signal provided by the second scanning line S2;

a first control circuit 12, respectively coupled to the first scanning line S1, the control terminal of the driving circuit 11 and the connection node N0, configured to control to connect the control terminal of the driving circuit 11 and the connection node N0 under the control of the first scanning signal.

Exemplarily, the display substrate includes a plurality of sub-pixels arranged in an array, and each sub-pixel includes a pixel circuit.

Exemplarily, in the sub-pixels located in the same column along the first direction, the data lines D1 are sequentially coupled to form an integrated structure.

Exemplarily, in the sub-pixels located in the same row along the second direction, the first scanning lines S1 are sequentially coupled to form an integrated structure. Exemplarily, in the sub-pixels located in the same row along the second direction, the second scanning lines S2 are sequentially coupled to form an integrated structure.

Exemplarily, the first direction includes the longitudinal direction, and the second direction includes the transverse direction.

Exemplarily, the display substrate includes: a light shielding layer, an isolation layer, a first buffer layer, a poly active layer, a first gate insulating layer, a first gate metal layer, a second gate insulating layer, a second gate metal layer, a first interlayer insulating layer, a second buffer layer, an oxide active layer (such as IGZO), a third gate insulating layer, a third gate metal layer, a second interlayer insulating layer, a first source-drain metal layer, a passivation layer, a first planarization layer, a second source-drain metal layer, a second planarization layer, an anode layer, a pixel definition layer, a spacer layer, a light emitting functional layer, a cathode layer and an encapsulation layer that are stacked on the base substrate along a direction away from the base substrate.

Exemplarily, the data line D1 is made of the second source-drain metal layer. The first scanning line S1 is made of a first gate metal layer.

Exemplarily, the second scanning line S2 includes a first scanning sub-pattern S21 and a third scanning sub-pattern S22, at least part of the first scanning sub-pattern S21 and at least part of the third scanning sub-pattern S22 are extending along the second direction. The compensation control circuit 13 includes a first transistor T1, and the first transistor T1 includes a first oxide active layer (such as the first active layer 51); in a direction perpendicular to the base substrate, at least a portion of the first oxide active layer is located between the first scanning sub-pattern S21 and the third scanning sub-pattern S22.

Exemplarily, the first scanning sub-pattern S21 is made of a second gate metal layer, and the third scanning sub-pattern S22 is made of a third gate metal layer. At least part of the first scanning sub-pattern S21 is located between the base substrate and the third scanning sub-pattern S22.

Exemplarily, the data writing-in circuit 41 includes a fourth transistor T4, the fourth transistor T4 includes a fourth active layer, the orthographic projection of the fourth active layer on the base substrate at least partially overlaps the orthographic projection of the data line D1 on the base substrate, the orthographic projection of the fourth active layer on the base substrate and the orthographic projection of the first oxide active layer on the base substrate are arranged along the second direction.

In the pixel circuit provided by the above embodiment, the first control circuit 12 is connected between the N1 node and the compensation control circuit 13, and the first control circuit 12 and the data writing-in circuit 41 are both controlled by the above-mentioned first scanning signal control and achieve the following beneficial effects.

Effect 1: At the moment tb, the second scanning signal written by the second scanning line S2 changes from a low level to a high level, and T1 is turned on. Between the moment tb and the moment tc, since the first control circuit 12 controls to disconnect the N1 node and the connection node N0, the voltages of the N2 node and the N3 node will no longer flow to the N1 node, which can ensure that when the data signal is written at the moment tc, the potential of the N1 node is still kept at the low voltage of Vi1, which ensures sufficient writing-in of the data signal.

Effect 2: At the end of the writing-in compensation phase P3, the second scanning signal written by the second scanning line S2 changes from a high level to a low level. By adding the first control circuit 12, at the end of the writing-in compensation phase P3, the first scanning signal written by the first scanning line S1 changes from the low level to the high level, so that at the end of the writing-in compensation phase P3, there is a process of pulling up N1 node, which is beneficial to reduce the data voltage required to display a black screen.

Effect 3: In the case where one GOA (S2) simultaneously provides the second scanning signal to the second scanning line S2 corresponding to two rows of sub-pixels. At the moment tb, the second scanning signal written by the second scanning line S2 changes from a low level to a high level, and T1 is turned on. Between the moment tb and the moment tc, since the first control circuit 12 controls to disconnect the N1 node and the connection node N0, it will not discharge to the N1 node between the moment tb and the moment tc, thereby ensuring that the same initial voltage of the N1 node before the data signal is written is the same.

Moreover, between the moment tb and the moment tc, because the first control circuit 12 controls to disconnect the electrical connection between the N1 node and the connection node N0, it is ensured that the voltage applied to the N1 node in the two rows of sub-pixels is the same, Therefore, even in the case of progressive scanning, the initial voltages of the N1 nodes in the two rows of sub-pixels before data signal writing-in are the same.

Therefore, when the two rows of sub-pixels include odd rows of sub-pixels and even rows of sub-pixels, there will be no difference in display brightness of the odd and even row of sub-pixels.

Therefore, when the display substrate provided by the embodiments of the present disclosure includes the above-mentioned pixel circuit, it also has the above-mentioned beneficial effects, which will not be repeated here.

As shown in FIGS. 3 to 8 and FIGS. 14 to 35, in some embodiments, the first control circuit 12 includes a ninth transistor T9, and the ninth transistor T9 includes a ninth active layer 59, the ninth active layer 59 includes at least a portion extending along the first direction;

The driving circuit 11 includes a third transistor T3, the orthographic projection of the gate electrode of the third transistor T3 on the base substrate and the orthographic projection of the ninth active layer 59 on the base substrate are arranged along the first direction;

The sub-pixel further includes: a first connection pattern 71, the second electrode of the ninth transistor T9 is coupled to the gate electrode of the third transistor T3 through the first connection pattern 71.

Exemplarily, the ninth active layer 59 is made of a poly active layer.

Exemplarily, the orthographic projection of the ninth active layer 59 on the base substrate at least partially overlaps with the orthographic projection of the second scanning line S2 on the base substrate.

Exemplarily, at least part of the orthographic projection of the ninth active layer 59 on the base substrate is located between the orthographic projection of the data line D1 on the base substrate and the orthographic projection of the first active layer on the base substrate.

Exemplarily, the orthographic projection of the ninth active layer 59 on the base substrate does not overlap the orthographic projection of the initialization control line R1 on the base substrate.

Exemplarily, the orthographic projection of the ninth active layer 59 on the base substrate is located between the orthographic projection of the gate electrode of the driving transistor on the base substrate and the orthographic projection of the initialization control line R1 on the base substrate.

Exemplarily, the first connection pattern 71 is made of the first source-drain metal layer.

Exemplarily, the first connection pattern 71 includes a portion extending along the first direction and a portion extending along a third direction, the third direction intersects both the first direction and the second direction.

Exemplarily, the first connection pattern 71 is coupled to the second electrode of the ninth transistor T9 through a via hole, and the first connection pattern 71 is coupled to the gate electrode of the third transistor T3 through the via hole.

Exemplarily, the orthographic projection of the first connection pattern 71 on the base substrate does not overlap the orthographic projection of the second scanning line S2 on the base substrate.

The above arrangement is beneficial to reduce the layout difficulty of the sub-pixels and reduce the parasitic capacitance generated by the ninth transistor T9.

As shown in FIGS. 14 to 25, in some embodiments, the first initialization circuit 14 in the pixel circuit includes a second transistor T2, the second transistor T2 includes a second active layer, and the second active layer includes at least a portion extending along the first direction; an orthographic projection of a part of the second active layer on the base substrate and an orthographic projection of a part of the ninth active layer on the base substrate are along arranged along the second direction;

The sub-pixel also includes a second connection pattern 72, and the second connection pattern 72 includes a portion extending along the first direction and a portion extending along the second direction; the second electrode of the second transistor T2 is coupled to the first connection pattern 71 through the second connection pattern 72.

Exemplarily, the sub-pixel further includes an initialization control line R1, the initialization control line R1 includes a first initialization sub-pattern R11 and a second initialization sub-pattern R12, at least part of the first initialization sub-pattern R11 and at least part of the second initialization sub-pattern R12 both extend along the second direction;

Exemplarily, the first initialization sub-pattern R11 is made of a second gate metal layer, and the second initialization sub-pattern R12 is made of a third gate metal layer. At least part of the first initialization sub-pattern R11 is located between the base substrate and the second initialization sub-pattern R12.

Exemplarily, the first initialization circuit 14 includes a second transistor T2, and the second active layer 52 includes a second oxide active layer; in a direction perpendicular to the base substrate, at least part of the second oxide active layer is located between the first initialization sub-pattern R11 and the second initialization sub-pattern R12.

Exemplarily, the first oxide active layer and the second oxide active layer are arranged along the first direction; the first oxide active layer and the second oxide active layer form an integral structure.

Exemplarily, the first oxide active layer and the second oxide active layer are staggered along the second direction.

Exemplarily, the orthographic projection of a part of the second active layer on the base substrate and the orthographic projection of a part of the ninth active layer on the base substrate are arranged along the second direction.

Exemplarily, the second connection pattern 72 is made of the first source-drain metal layer.

Exemplarily, the orthographic projection of the second connection pattern 72 on the base substrate at least partially overlaps the orthographic projection of the second scanning line S2 on the base substrate.

Exemplarily, the orthographic projection of the second connection pattern 72 on the base substrate at least partially overlaps the orthographic projection of the first scanning sub-pattern S21 on the base substrate. The orthographic projection of the second connection pattern 72 on the base substrate at least partially overlaps the orthographic projection of the third scanning sub-pattern S22 on the base substrate.

Exemplarily, the second connection pattern 72 and the first connection pattern 71 form an integral structure.

Exemplarily, the orthographic projection of the second connection pattern 72 on the base substrate at least partially overlaps the orthographic projection of the first active layer 51 on the base substrate.

Exemplarily, the second connection pattern 72 is coupled to the second electrode of the second transistor T2 through a via hole.

The above setting is beneficial to reduce the layout difficulty of the sub-pixels. The above arrangement enables the second transistor to directly initialize the gate electrode of the third transistor, and the driving method is simple.

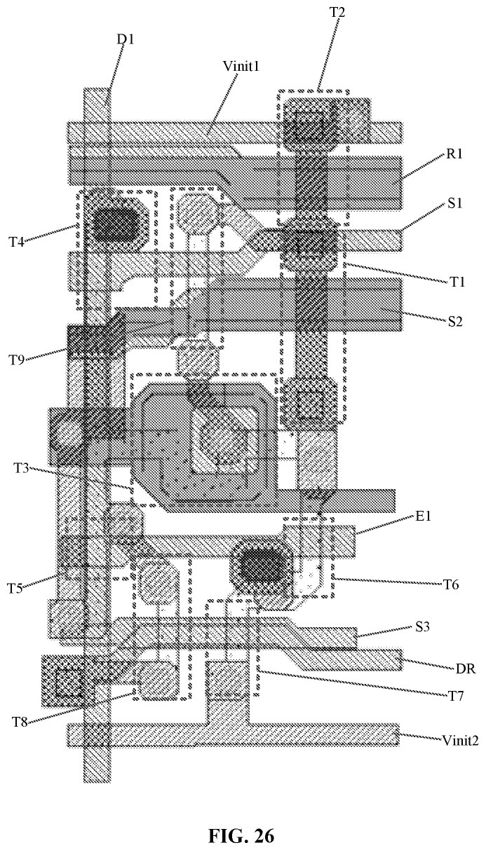

As shown in FIG. 26 to FIG. 31, in some embodiments, the first initialization circuit 14 in the pixel circuit includes a second transistor T2, the second transistor T2 includes a second active layer, and the second active layer includes at least a portion extending along the first direction; an orthographic projection of a part of the second active layer on the base substrate and the orthographic projection of a part of the ninth active layer on the base substrate are arranged along the second direction;

The sub-pixel also includes a third connection pattern 73, and the third connection pattern 73 includes at least a portion extending along the second direction; the second electrode of the second transistor T2 is connected to the first electrode of the ninth transistor T9 through the third connection pattern 73.

Exemplarily, the third connection pattern 73 is made of the first source-drain metal layer.

Exemplarily, the orthographic projection of the third connection pattern 73 on the base substrate at least partially overlaps the orthographic projection of the first scanning line S1 on the base substrate.

Exemplarily, the orthographic projection of the third connection pattern 73 on the base substrate does not overlap the orthographic projection of the first scanning sub-pattern S21 on the base substrate. The orthographic projection of the third connection pattern 73 on the base substrate does not overlap the orthographic projection of the third scanning sub-pattern S22 on the base substrate.

Exemplarily, the third connection pattern 73 is coupled to the second electrode of the second transistor T2 through a via hole. The third connection pattern 73 is coupled to the first electrode of the ninth transistor T9 through a via hole.

Exemplarily, the orthographic projection of the third connection pattern 73 on the base substrate does not overlap the orthographic projection of the initialization control line R1 on the base substrate.

Exemplarily, the orthographic projection of the third connection pattern 73 on the base substrate at least partially overlaps the orthographic projection of the initialization control line R1 on the base substrate.

Exemplarily, the orthographic projection of the third connection pattern 73 on the base substrate is located between the orthographic projection of the initialization control line R1 on the base substrate and the orthographic projection of the second scanning line S2 on the base substrate.

The above setting is beneficial to reduce the layout difficulty of the sub-pixels. The above arrangement enables the second transistor T2 to initialize the gate electrode T3-g of the third transistor T3 through the ninth transistor T9.

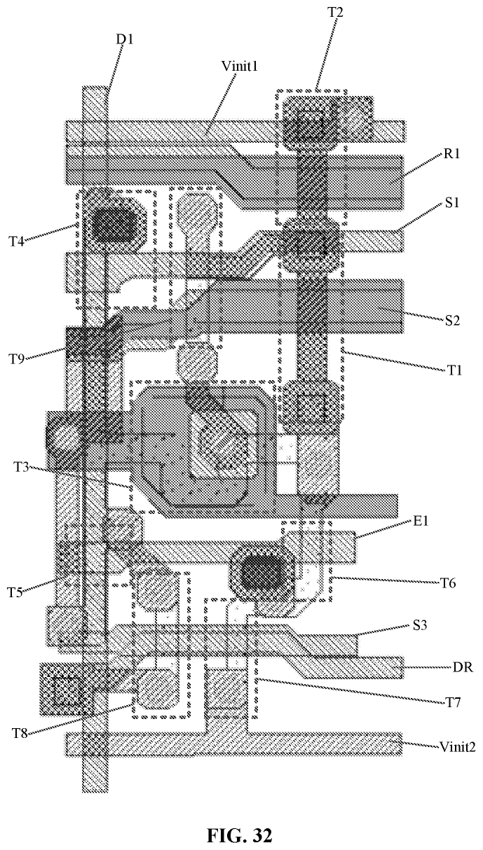

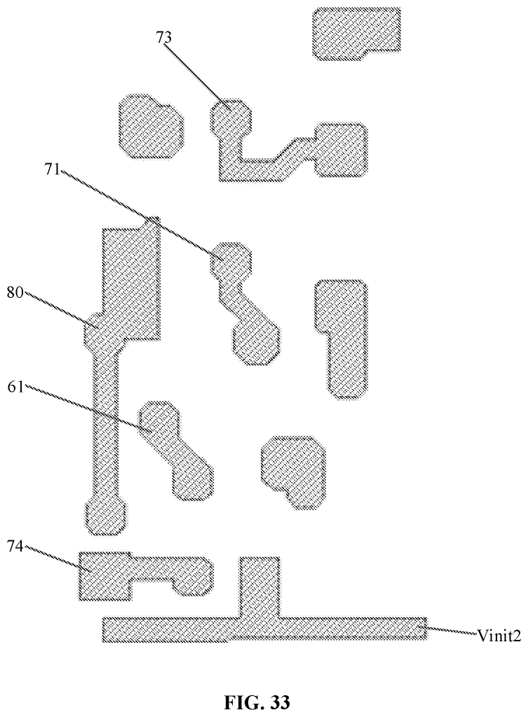

As shown in FIG. 32 and FIG. 33, in some embodiments, the orthographic projection of the third connection pattern 73 on the base substrate is set to at least partially overlap the orthographic projection of the first scanning line S1 on the base substrate.

Exemplarily, the third connection pattern 73 includes a portion extending along the first direction, a portion extending along the second direction, and a portion extending along a fourth direction. The fourth direction intersects both the first direction and the second direction.

Exemplarily, the orthographic projection of a part of the third connection pattern 73 on the base substrate is located inside the orthographic projection of the first scanning line S1 on the base substrate. The orthographic projection of another part of the third connection pattern 73 on the base substrate is located inside the orthographic projection of the ninth active layer on the base substrate.

The above arrangement is beneficial to increase the transmittance of the display substrate.

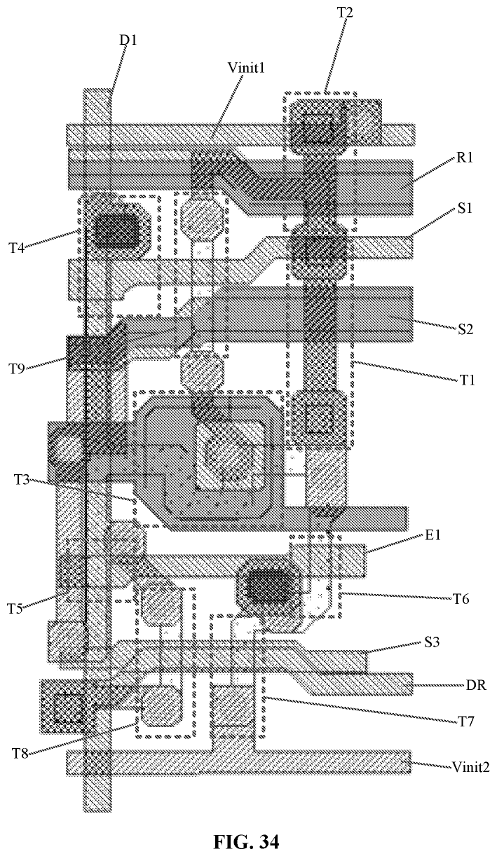

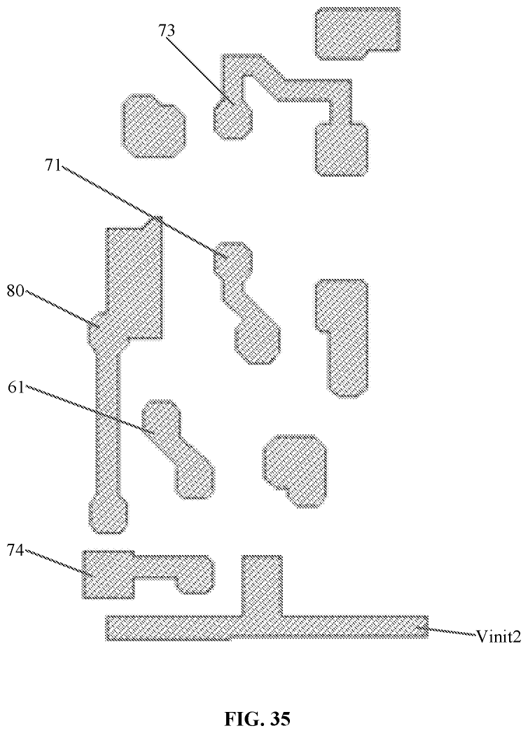

As shown in FIG. 34 and FIG. 35, in some embodiments, the sub-pixels further includes an initialization control line R1, and the orthographic projection of the third connection pattern 73 on the base substrate at least partially overlaps the orthographic projection of the initialization control line R1 on the base substrate.

Exemplarily, the initialization control line R1 includes a first initialization sub-pattern R11 and a second initialization sub-pattern R12.

Exemplarily, the orthographic projection of the third connection pattern 73 on the base substrate at least partially overlaps the orthographic projection of the first initialization sub-pattern R11 on the base substrate. The orthographic projection of the third connection pattern 73 on the base substrate at least partially overlaps the orthographic projection of the second initialization sub-pattern R12 on the base substrate.

Exemplarily, the third connection pattern 73 includes a portion extending along the first direction, a portion extending along the second direction, and a portion extending along the third direction.

The above arrangement is beneficial to increase the transmittance of the display substrate.

As shown in FIGS. 14 to 34, in some embodiments, the sub-pixels further include:

A data line D1, a reset voltage line DR, a first scanning line S1 and a third scanning line S3; wherein the data line D1 includes at least a portion extending along the first direction, and the first scanning line S1 includes at least a portion extending along the second direction, the third scanning line S3 includes at least a portion extending along the second direction, and the second direction intersects the first direction;

A data writing-in circuit 41, respectively coupled to the first scanning line S1, the data line D1 and the second terminal of the driving circuit 11, for controlling to connect the data line D1 and the second terminal of the driving circuit 11 under the control of the first scanning signal provided by the first scanning line S1;

A reset circuit 20, respectively coupled to the third scanning line S3 and the reset voltage line DR, and coupled to the first terminal or the second terminal of the driving circuit 11, and is used to, under the control of the third scanning signal provided by the third scanning line S3, control to connect the reset voltage line DR and the second terminal of the driving circuit 11; or control to connect the reset voltage line DR and the first terminal of the driving circuit 11.

Exemplarily, the reset voltage line DR includes at least a portion extending along the first direction. Exemplarily, the reset voltage line DR is made of the second source-drain metal layer or the first source-drain metal layer. Exemplarily, in the sub-pixels located in the same column along the first direction, the reset voltage lines DR are sequentially coupled to form an integrated structure.

Exemplarily, the reset voltage line DR includes at least a portion extending along the second direction. Exemplarily, the reset voltage line DR is made of a third gate metal layer. Exemplarily, the orthographic projection of the reset voltage line DR on the base substrate at least partially overlaps the orthographic projection of the third scanning line S3 on the base substrate. Exemplarily, in the sub-pixels located in the same row along the second direction, the reset voltage lines DR are sequentially coupled to form an integrated structure.

Exemplarily, the reset voltage line DR includes a reference signal line.

Exemplarily, in the sub-pixels located in the same row along the second direction, the third scanning lines S3 are sequentially coupled to form an integrated structure. Exemplarily, both the first scanning line S1 and the third scanning line S3 are made of a first gate metal layer.

In the pixel circuit provided by the above-mentioned embodiments, by setting the reset circuit 20, a bias voltage opposite in sign to that in the light emitting phase P4 can be applied to the driving circuit 11 in the bias compensation phase P2, thereby compensating that the characteristic deviation of the driving circuit 11 when it works at a certain bias for a period of time, and the problems such as short-term afterimage and slow response time will be improved. Moreover, when driving at low frequency, it can compensate the difference in brightness caused by the characteristic deviation of the driving circuit 11 in the light emitting period for a long time, and improve the flicker phenomenon. Therefore, when the display substrate provided by the above-mentioned embodiment includes the above-mentioned pixel circuit, it also has the above-mentioned beneficial effects, which will not be repeated here.

In addition, when the display substrate provided by the above embodiment includes the above pixel circuit, it can realize specific bias compensation for the driving circuit 11 in each pixel circuit in the display substrate, and has a good compensation effect. In addition, since the reset voltage provided by the reset voltage line DR can be adjusted independently, it can provide an appropriate bias voltage to each pixel circuit in the display substrate as required.

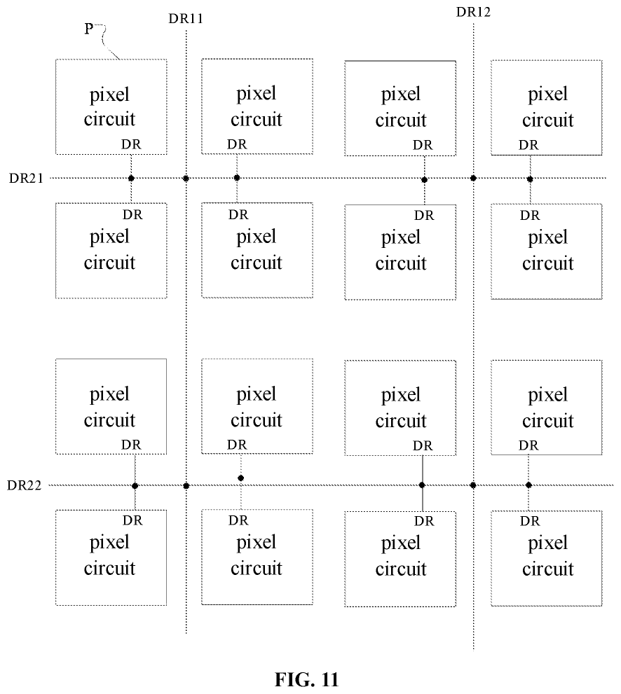

As shown in FIG. 11, in some embodiments, the display substrate includes a plurality of pixel circuits P arranged in an array, a plurality of reset voltage lines DR11, DR12, DR21, DR22, and reset voltage lines DR11, DR12, DR21, DR22 are all used to provide a reset voltage.

As shown in FIG. 10, the reset voltage lines DR11 and DR12 extend along the column direction, and the reset voltage lines DR21 and DR22 extend along the row direction. Pixel circuits in two adjacent rows can be connected to the reset voltage line DR extending in the same row direction. The reset voltage line DR can be located between the two adjacent rows of pixel driving circuits 11, and the reset voltage line DR extending along the column direction can be connected to a plurality of reset voltage lines DR extending along the row direction intersecting with the reset voltage line DR, so that the multiple reset voltage lines DR can be form a grid structure. Wherein, the reset voltage line DR extending along the column direction may be located in the area where the red pixel circuit is located. In addition, in the same row of pixels, two pixel circuits in adjacent columns can be arranged in mirror to facilitate wiring.

As shown in FIG. 14 to FIG. 34, in some embodiments, the driving circuit 11 includes a third transistor T3, and the reset circuit 20 includes an eighth transistor T8;

The gate electrode T8-g of the eighth transistor T8 is coupled to the third scanning line S3, the first electrode of the eighth transistor T8 is coupled to the reset voltage line DR, and the second electrode of the eighth transistor T8 is coupled to the first electrode of the third transistor T3;

The reset voltage line DR includes at least a portion extending along the second direction; the orthographic projection of the reset voltage line DR on the base substrate and the orthographic projection of the gate electrode of the driving transistor on the base substrate are arranged along the first direction.

Exemplarily, the gate electrode T3-g of the third transistor T3 is made of the first gate metal layer. The gate electrode T8-g of the eighth transistor T8 and the third scanning line S3 form an integral structure.

Exemplarily, the reset voltage line DR is made of a third gate metal layer.

Exemplarily, the first electrode of the eighth transistor T8 is coupled to the reset voltage line DR through the fourth connection pattern 74. Exemplarily, the fourth connection pattern 74 includes a portion extending along the second direction.

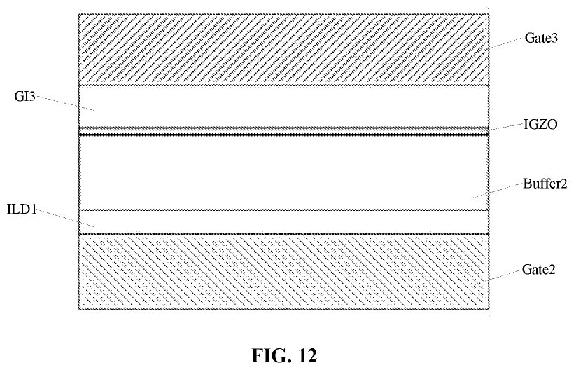

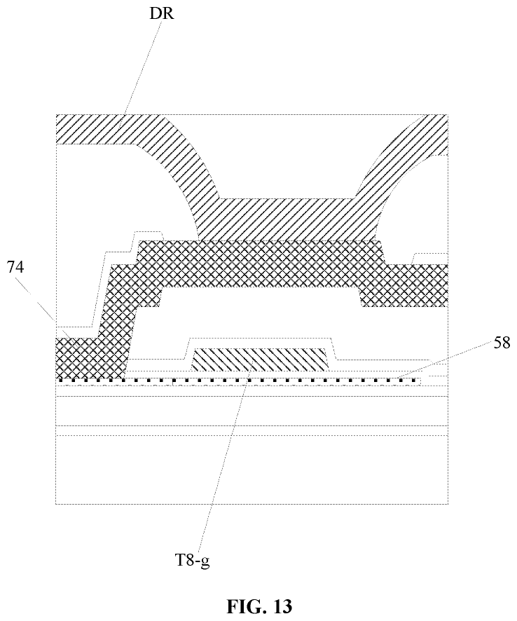

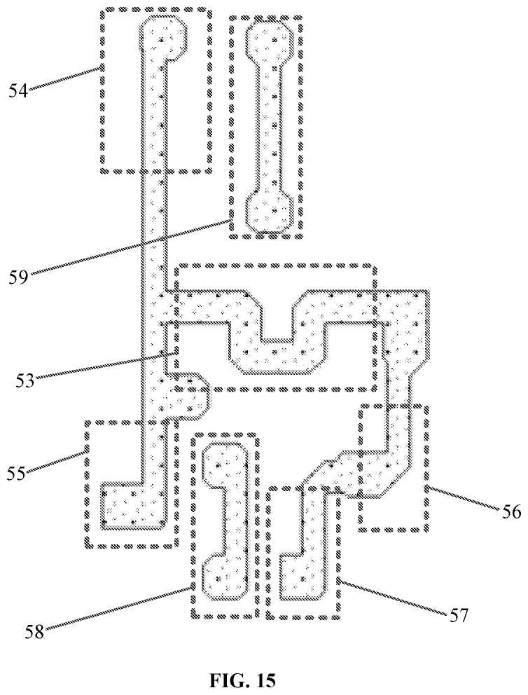

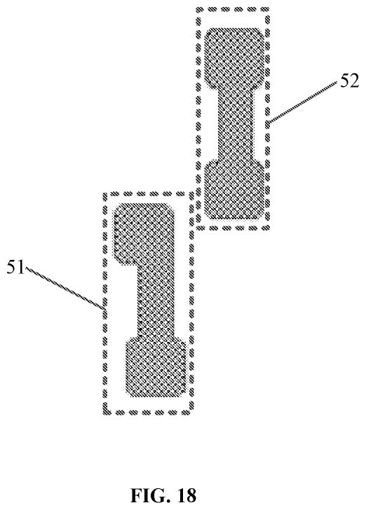

It should be noted that FIG. 15 shows that T3 includes the third active layer 53, T4 includes the fourth active layer 54, T5 includes the fifth active layer 55, T6 includes the sixth active layer 56, and T7 includes the seventh active layer 57. FIG. 18 illustrates the first active layer 51 included in T1 and the second active layer 52 included in T2. FIG. 12 illustrates the second gate metal layer Gate2, the first interlayer insulating layer ILD1, the second buffer layer Buffer2, the oxide layer (IGZO), the third gate insulating layer GI3, and the third gate metal layer Gate3. FIG. 13 shows that the first electrode of the eighth transistor T8 is coupled to the reset voltage line DR through the fourth connection pattern 74.

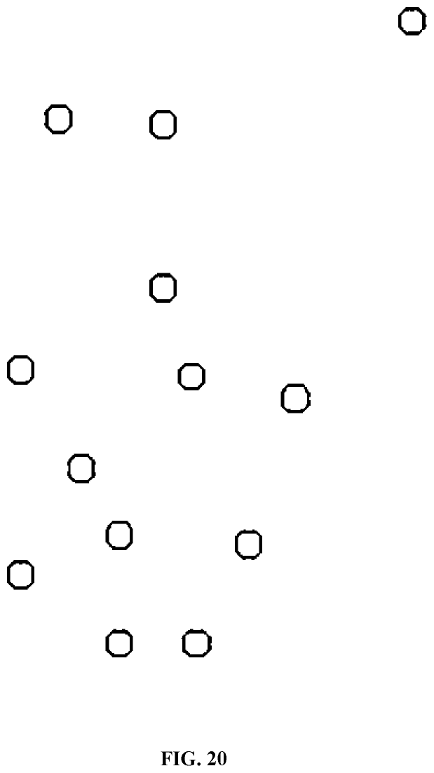

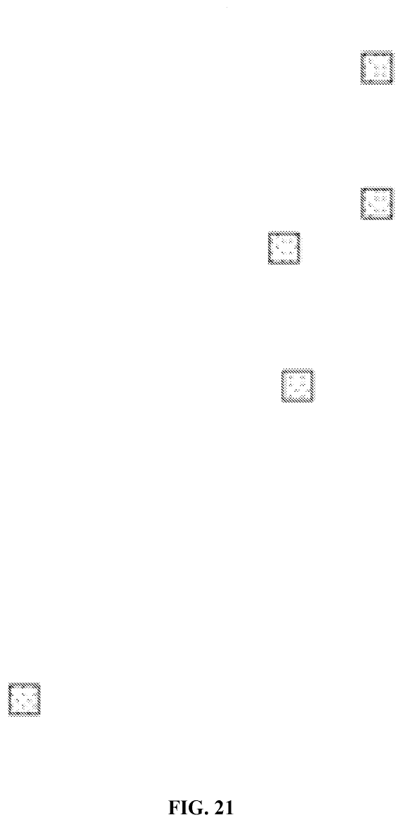

It should be noted that the first connection holes in FIG. 20 are used to connect the first source-drain metal layer and a corresponding structures below the first source-drain metal layer, and the depths of the first connection holes in FIG. 20 may be the same or different. The second connection holes in FIG. 21 are used to connect the first source-drain metal layer and the corresponding structures below the first source-drain metal layer, and the depths of the second connection holes in FIG. 21 may be the same or different.

It should be noted that in the embodiments corresponding to FIG. 26, FIG. 32 and FIG. 34, some single-layer film layers are not shown, and the corresponding single-layer film layer in FIG. 14 can be referred.

The above setting is beneficial to reduce the layout difficulty of the sub-pixels.

In some embodiments, the eighth transistor T8 includes an eighth active layer 58 including at least a portion extending along the first direction.

Exemplarily, the orthographic projection of the eighth active layer 58 on the base substrate at least partially overlaps the orthographic projection of the reset voltage line DR on the base substrate.

Exemplarily, the orthographic projection of the light emitting control line E1 on the base substrate is located between the orthographic projection of the eighth active layer 58 on the base substrate and the orthographic projection of the gate electrode T3-g of the third transistor T3 on the base substrate.

Exemplarily, the second electrode of the eighth transistor T8 is coupled to the first electrode of the third transistor T3 through the first conductive connection portion 61. The orthographic projection of the first conductive connection portion 61 on the base substrate at least partially overlaps the orthographic projection of the light emitting control line E1 on the base substrate.

Exemplarily, the first conductive connection portion 61 is made of the first source-drain metal layer.

Exemplarily, the orthographic projection of the first conductive connection portion 61 on the base substrate partially overlaps the orthographic projection of the data line D1 on the base substrate.

Exemplarily, the orthographic projection of the first conductive connection portion 61 on the base substrate does not overlap the orthographic projection of the data line D1 on the base substrate, and does not overlap the orthographic projection of the reset voltage line DR on the base substrate.

Exemplarily, the orthographic projection of the first conductive connection portion 61 on the base substrate does not overlap the orthographic projection of the second electrode plate C2 of the storage capacitor C on the base substrate.

Exemplarily, the first conductive connection portion 61 is respectively coupled to the second electrode of the eighth transistor T8 and the first electrode of the third transistor T3 through corresponding via holes.

The above setting is beneficial to reduce the layout difficulty of the sub-pixels.

In some embodiments, the second initialization circuit 32 includes a seventh transistor T7, the gate electrode of the seventh transistor T7 is coupled to the third scanning line S3, the first electrode of the seventh transistor T7 is connected to the second initialization voltage line Vinit2.

Exemplarily, the seventh transistor T7 includes a seventh active layer, and the eighth active layer 58 and the seventh active layer are arranged along the second direction. The orthographic projection of the eighth active layer 58 on the base substrate is located between the orthographic projection of the seventh active layer on the base substrate and the orthographic projection of the data line D1 on the base substrate.

In some embodiments, the sub-pixel further includes a light emitting control line E1, and the light emitting control line E1 includes at least a portion extending along the second direction;

The light emitting control circuit 31 includes a fifth transistor T5 and a sixth transistor T6, the gate electrode of the fifth transistor T5 is coupled to the light emitting control line E1, the gate electrode of the sixth transistor T6 is coupled to the light emitting control line E1;

The fifth transistor T5 includes a fifth active pattern, the sixth transistor T6 includes a sixth active pattern, and the fifth active pattern and the sixth active pattern are arranged along the second direction.

Embodiments of the present disclosure also provide a display device, including the display substrate provided in the above embodiments.

In the display substrate provided by the above-mentioned embodiment, the first control circuit 12 is connected between the N1 node and the compensation control circuit 13, and the first control circuit 12 and the data writing-in circuit 41 are controlled by the first scanning signal, and the following beneficial effects are achieved.

Effect 1: At the moment tb, the second scanning signal written by the second scanning line S2 changes from a low level to a high level, and T1 is turned on. Between the moment tb and the moment tc, since the first control circuit 12 controls to disconnect the N1 node and the connection node N0, the voltages of the N2 node and the N3 node will no longer flow to the N1 node, which can ensure that when the data signal is written at the moment tc, the potential of the N1 node is still kept at the low voltage of Vi1, which ensures sufficient writing-in of the data signal.

Effect 2: At the end of the writing-in compensation phase P3, the second scanning signal written by the second scanning line S2 changes from a high level to a low level. By adding the first control circuit 12, at the end of the writing-in compensation phase P3, the first scanning signal written by the first scanning line S1 changes from the low level to the high level, so that at the end of the writing-in compensation phase P3, there is a process of pulling up N1 node, which is beneficial to reduce the data voltage required to display a black screen.

Effect 3: In the case where one GOA (S2) simultaneously provides the second scanning signal to the second scanning line S2 corresponding to two rows of sub-pixels. At the moment tb, the second scanning signal written by the second scanning line S2 changes from a low level to a high level, and T1 is turned on. Between the moment tb and the moment tc, since the first control circuit 12 controls to disconnect the N1 node and the connection node N0, it will not discharge to the N1 node between the moment tb and the moment tc, thereby ensuring that the same initial voltage of the N1 node before the data signal is written is the same. Moreover, between the moment tb and the moment tc, because the first control circuit 12 controls to disconnect the electrical connection between the N1 node and the connection node N0, it is ensured that the voltage applied to the N1 node in the two rows of sub-pixels is the same, Therefore, even in the case of progressive scanning, the initial voltages of the N1 nodes in the two rows of sub-pixels before data signal is written are the same. Therefore, when the two rows of sub-pixels include odd rows of sub-pixels and even rows of sub-pixels, there will be no difference in display brightness of the odd and even row of sub-pixels.

Therefore, the display device provided by the embodiments of the present disclosure also has the above-mentioned beneficial effects when it includes the above-mentioned display substrate, which will not be repeated here.

It should be noted that the display device can be any product or component with a display function such as a TV, a monitor, a digital photo frame, a mobile phone, a tablet computer, etc., wherein the display device also includes a flexible circuit board, a printed circuit board and a back panel etc.

It should be noted that “same layer” in the embodiments of the present disclosure may refer to film layers on the same structural layer. Or, for example, the film layers in the same layer may be a layer structure formed by using the same film forming process to form a film layer for forming a specific pattern, and then using the same mask to pattern the film layer through a patterning process. Depending on the specific pattern, one patterning process may include multiple exposure, development or etching processes, and the specific pattern in the formed layer structure may be continuous or discontinuous. These specific pattern may also be at different heights or have different thicknesses.

In each method embodiment of the present disclosure, the serial numbers of the steps cannot be used to limit the order of the steps. For those of ordinary skill in the art, the order of the steps can be changed without creative work. It is also within the protection scope of the present disclosure.

It should be noted that each embodiment in the present disclosure is described in a progressive manner, the same and similar parts of each embodiment can be referred to each other, and each embodiment focuses on the differences from other embodiments. In particular, for the method embodiments, since they are basically similar to the product embodiments, the description is relatively simple, and for relevant parts, the part of the description of the product embodiments may be referred.

Unless otherwise defined, the technical terms or scientific terms used in the present disclosure shall have the usual meanings understood by those skilled in the art to which the present disclosure belongs. “First”, “second” and similar words used in the present disclosure do not indicate any order, quantity or importance, but are only used to distinguish different components. “Comprising” or “including” and similar words mean that the elements or items appearing before the word include the elements or items listed after the word and their equivalents, without excluding other elements or items. Words such as “connected”, “coupled” are not limited to physical or mechanical connections, but may include electrical connections, whether direct or indirect. “Up”, “Down”, “Left”, “Right” and so on are only used to indicate the relative positional relationship. When the absolute position of the described object changes, the relative positional relationship may also change accordingly.

It will be understood that when an element such as a layer, film, region, or substrate is referred to as being “on” or “under” another element, it can be “directly on” or “under” the other element, or intervening elements may be present.

In the description of the above embodiments, specific features, structures, materials or characteristics may be combined in any one or more embodiments or examples in an appropriate manner.

The above is only a specific implementation of the present disclosure, but the scope of protection of the present disclosure is not limited thereto. Those skilled in the art can easily make changes or substitutions within the technical scope of the present disclosure, which should fall within the protection scope of the present disclosure. Therefore, the protection scope of the present disclosure should be determined by the protection scope of the claims.

1. A pixel circuit, comprising: a driving circuit, a data writing-in circuit, a compensation control circuit and a first control circuit; wherein
the data writing-in circuit is respectively coupled to a first scanning line, a data line, and a second terminal of the driving circuit, and is configured to control to connect the data line and the second terminal of the driving circuit under the control of a first scanning signal provided by the first scanning line;
the compensation control circuit is respectively coupled to a second scanning line, a first terminal of the driving circuit and a connection node, and is configured to control to connect the first terminal of the driving circuit and the connection node under the control of a second scanning signal provided by the second scanning line;
the first control circuit is respectively coupled to the first scanning line, a control terminal of the driving circuit and the connection node, and is configured to control to connect the control terminal of the driving circuit and the connection node under the control of the first scanning signal.

2. The pixel circuit according to claim 1, wherein the pixel circuit further comprises:
a first initialization circuit, the first initialization circuit is respectively coupled to an initialization control line, a first initialization voltage line and the control terminal of the driving circuit, and is configured to control to connect the first initialization voltage line and the control terminal of the driving circuit under the control of an initialization control signal provided by the initialization control line.

3. The pixel circuit according to claim 1, wherein the pixel circuit further comprises:
a first initialization circuit, wherein the first initialization circuit is respectively coupled to an initialization control line, a first initialization voltage line and the connection node, and is configured to control to connect the first initialization voltage line and the connection node under the control of an initialization control signal provided by the initialization control line.

4. The pixel circuit according to claim 1, wherein the pixel circuit further comprises:
a reset circuit, wherein the reset circuit is respectively coupled to a third scanning line, a reset voltage line and the second terminal of the driving circuit, is configured to control to connect the reset voltage line and the second terminal of the driving circuit under the control of a third scanning signal provided by the third scanning line.

5. The pixel circuit according to claim 1, wherein the pixel circuit further comprises:
a reset circuit, the reset circuit is respectively coupled to a third scanning line, a reset voltage line and the first terminal of the driving circuit, and is configured to control to connect the reset voltage line and the first terminal of the driving circuit under the control of a third scanning signal provided by the third scanning line.

6. The pixel circuit according to claim 1, wherein the pixel circuit further comprises: a light emitting control circuit, an energy storage circuit and a light emitting element;
the light emitting control circuit is respectively coupled to a light emitting control line, the first terminal of the driving circuit and the light emitting element, and is configured to control to connect the first terminal of the driving circuit and the light emitting element under the control of a light emitting control signal provided by the light emitting control line;
the light emitting control circuit is also coupled to a first voltage line and the second terminal of the driving circuit, and is configured to control to connect the first voltage line and the second terminal of the driving circuit under the control of the light emitting control signal;
the energy storage circuit is respectively coupled to the control terminal of the driving circuit and the first voltage line.

7. The pixel circuit according to claim 4, wherein the pixel circuit further comprises: a second initialization circuit and a light emitting element;
the second initialization circuit is respectively coupled to the third scanning line, a second initialization voltage line and the light emitting element, and is configured to control to connect the second initialization voltage line and the light emitting element under the control of the third scanning signal provided by the third scanning line;
wherein the pixel circuit further comprises a first initialization circuit, the first initialization circuit is coupled to a first initialization voltage line, and the first initialization voltage line is multiplexed as the reset voltage line.

8. (canceled)

9. The pixel circuit according to claim 1, wherein the compensation control circuit includes a first transistor, the driving circuit includes a third transistor, the data writing-in circuit includes a fourth transistor, and the first control circuit includes a ninth transistor;
a gate electrode of the first transistor is coupled to the second scanning line, a first electrode of the first transistor is coupled to a second electrode of the third transistor, and a second electrode of the first transistor is coupled to the connection node;
a gate electrode of the fourth transistor is coupled to the first scanning line, a first electrode of the fourth transistor is coupled to the data line, and a second electrode of the fourth transistor is coupled to a first electrode of the third transistor;
a gate electrode of the ninth transistor is coupled to the first scanning line, a first electrode of the ninth transistor is coupled to the connection node, and a second electrode of the ninth transistor is coupled to a gate electrode of the third transistor.

10. The pixel circuit according to claim 2, wherein the first initialization circuit comprises a second transistor, a gate electrode of the second transistor is coupled to the initialization control line, a first electrode of the second transistor is coupled to the first initialization voltage line, and a second electrode of the second transistor is coupled to the control terminal of the driving circuit.

11. The pixel circuit according to claim 3, wherein the first initialization circuit comprises a second transistor, a gate electrode of the second transistor is coupled to the initialization control line, and a first electrode of the second transistor is connected to the first initialization voltage line, and a second electrode of the second transistor is coupled to the connection node.

12. The pixel circuit according to claim 4, wherein the reset circuit comprises an eighth transistor;
a gate electrode of the eighth transistor is coupled to the third scanning line, a first electrode of the eighth transistor is coupled to the reset voltage line, and a second electrode of the eighth transistor is coupled to the second terminal of the driving circuit.

13. The pixel circuit according to claim 5, wherein the reset circuit comprises an eighth transistor;
a gate electrode of the eighth transistor is coupled to the third scanning line, a first electrode of the eighth transistor is coupled to the reset voltage line, and a second electrode of the eighth transistor is coupled to the first terminal of the driving circuit.

14. The pixel circuit according to claim 6, wherein the light emitting control circuit comprises a fifth transistor and a sixth transistor;
a gate electrode of the fifth transistor is coupled to the light emitting control line, a first electrode of the fifth transistor is coupled to the first voltage line, and a second electrode of the fifth transistor is coupled to the second terminal of the driving circuit;
a gate electrode of the sixth transistor is coupled to the light emitting control line, a first electrode of the sixth transistor is coupled to one terminal of the driving circuit, and a second electrode of the sixth transistor is coupled to the light emitting element.

15. The pixel circuit according to claim 7, wherein the second initialization circuit comprises a seventh transistor,
a gate electrode of the seventh transistor is coupled to the third scanning line, a first electrode of the seventh transistor is coupled to the second initialization voltage line, and a second electrode of the seventh transistor is coupled to the light emitting element.

16. A driving method, applied to the pixel circuit according to claim 1, wherein the display period includes a writing-in compensation phase, and the writing-in compensation phase includes: a writing-in control phase and a non-writing-in control phase; the driving method includes:
in the entire writing-in compensation phase, the compensation control circuit controlling to connect the first terminal of the driving circuit and the connection node under the control of the second scanning signal;
in the writing-in control phase, the data writing-in circuit controlling to connect the data line and the second terminal of the driving circuit under the control of the first scanning signal;
controlling to connect the control terminal of the driving circuit and the connection node under the control of the first scanning signal;
in the non-writing-in control phase, the data writing-in circuit controlling to not connect the data line and the second terminal of the driving circuit under the control of the first scanning signal; the first control circuit controlling to not connect the control terminal of the driving circuit and the connection node under the control of the first scanning signal.

17. (canceled)

18. The driving method according to claim 16, wherein the display period further includes an initialization phase; the driving method further includes:
in the initialization phase, the first initialization circuit in the pixel circuit controlling to connect the first initialization voltage line and the control terminal of the driving circuit under the control of the initialization control signal; or
in the initialization phase, the first initialization circuit controlling to connect the first initialization voltage line and the connection node under the control of the initialization control signal, and the first control circuit controlling to connect the control terminal of the driving circuit and the connection node under the control of the first scanning signal;
or
wherein the display period further includes a bias compensation phase and a light emitting phase, the driving method comprises:
in the bias compensation phase, the reset circuit controlling to connect the reset voltage line and the second terminal of the driving circuit under the control of the third scanning signal; or controlling to connect between the reset voltage line and the first terminal of the driving circuit;
in the light emitting phase, the light emitting control circuit in the pixel circuit controlling to connect the first voltage line and the second terminal of the driving circuit under the control of the light emitting control signal, and controlling to connect the first terminal of the driving circuit and the light emitting element, and the driving circuit driving the light emitting element to emit light.

19. (canceled)

20. A display substrate, comprising a base substrate and a plurality of sub-pixels arranged on the base substrate, wherein the sub-pixel comprises the pixel circuit according to claim 1; the sub-pixel further comprises:
a data line, a first scanning line and a second scanning line; wherein the data line includes at least a portion extending along a first direction, the first scanning line includes at least a portion extending along a second direction, the third scanning line includes at least a portion extending along the second direction, the second direction intersects the first direction;
a data writing-in circuit, respectively coupled to the first scanning line, the data line and the second terminal of the driving circuit, configured to control to connect the data line and the second terminal of the driving circuit under the control of the first scanning signal provided by the first scanning line;
a compensation control circuit, respectively coupled to the second scanning line, the first terminal of the driving circuit and the connection node, configured to control to connect the first terminal of the driving circuit and the connection node under the control of the second scanning signal provided by the second scanning line;
a first control circuit, respectively coupled to the first scanning line, the control terminal of the driving circuit and the connection node, configured to control to connect the control terminal of the driving circuit and the connection node under the control of the first scanning signal.

21. The display substrate according to claim 20, wherein the first control circuit includes a ninth transistor, the ninth transistor includes a ninth active layer, and the ninth active layer includes at least a portion extending along the first direction;
the driving circuit includes a third transistor, an orthographic projection of a gate electrode of the third transistor on the base substrate and an orthographic projection of the ninth active layer on the base substrate are arranged along the first direction;
the sub-pixel further includes: a first connection pattern, a second electrode of the ninth transistor is coupled to the gate electrode of the third transistor through the first connection pattern;
wherein the first initialization circuit in the pixel circuit includes a second transistor, the second transistor includes a second active layer, and the second active layer includes at least a portion extending along the first direction; an orthographic projection of a part of the second active layer on the base substrate and an orthographic projection of a part of the ninth active layer on the base substrate are arranged along the second direction;
the sub-pixel also includes a second connection pattern, and the second connection pattern includes a portion extending along the first direction and a portion extending along the second direction; a second electrode of the second transistor is coupled to the first connection pattern through the second connection pattern.

22. (canceled)

23. The display substrate according to claim 21, wherein the first initialization circuit in the pixel circuit includes a second transistor, the second transistor includes a second active layer, and the second active layer includes at least a portion extending along the first direction; an orthographic projection of a part of the second active layer on the base substrate and an orthographic projection of a part of the ninth active layer on the base substrate are arranged along the second direction;
the sub-pixel also includes a third connection pattern, and the third connection pattern includes at least a portion extending along the second direction; a second electrode of the second transistor is coupled to the first electrode of the ninth transistor through the third connection pattern;
wherein an orthographic projection of the third connection pattern on the base substrate at least partially overlaps an orthographic projection of the first scanning line on the base substrate;
or
wherein the sub-pixel further comprises an initialization control line, and the orthographic projection of the third connection pattern on the base substrate at least partially overlaps an orthographic projection of the initialization control line on the base substrate.

24. (canceled)

25. (canceled)

26. A display device comprising the display substrate according to claim 20.
